(19) United States
(12) Patent Application Publication
(10) Pub. No.: US 2015/0144198 A1
(43) Pub. Date: May 28, 2015

(54) SOLAR CELL MATERIALS

(71) Applicants: Michael D. Irwin, Dallas, TX (US); Robert D. Maher, III, Plano, TX (US); Jerred A. Chute, Dallas, TX (US); Vivek V. Dhas, Dallas, TX (US)

(72) Inventors: Michael D. Irwin, Dallas, TX (US); Robert D. Maher, III, Plano, TX (US); Jerred A. Chute, Dallas, TX (US); Vivek V. Dhas, Dallas, TX (US)

(21) Appl. No.: 14/281,196

(22) Filed: May 19, 2014

Related U.S. Application Data
(60) Provisional application No. 61/909,168, filed on Nov. 26, 2013.

(51) Int. Cl. H01G 9/20; H01L 51/00

(52) U.S. Cl. CPC H01G 9/2059; H01G 9/2027; H01L 51/006; H01L 51/0052; H01L 51/0058; H01L 51/0068; H01L 51/0074; H01L 51/0071; H01L 51/0061; H01L 51/0069; H01L 51/0072
USPC 136/263

(57) ABSTRACT

A photovoltaic cell of improved construction may include an active layer comprising first and second active material, and a dye. Either of the first and second active material may include a copper-oxide compound. The active layer may further include a thin-coat interfacial layer, which may coat at least a portion of either of the first and second active material. The dye may include a primary electron donor moiety, a core moiety, and an electron-withdrawing moiety.

### RELATED APPLICATIONS

This application claims the benefit of U.S. Provisional Application No. 61/909,168, filed Nov. 26, 2013, which is incorporated herein by reference for all purposes.

### BACKGROUND

Use of photovoltaics (PVs) to generate electrical power from solar energy or radiation may provide many benefits, including, for example, a power source, low or zero emissions, power production independent of the power grid, durable physical structures (no moving parts), stable and reliable systems, modular construction, relatively quick installation, safe manufacture and use, and good public opinion and acceptance of use.

The features and advantages of the present disclosure will be readily apparent to those skilled in the art. While numerous changes may be made by those skilled in the art, such changes are within the spirit of the invention.

### BRIEF DESCRIPTION OF THE DRAWINGS

FIG. 1 is a general design scheme for a photoactive composition of matter of some embodiments of the present disclosure.

FIG. 2 is a general design scheme for a photoactive composition of matter of some embodiments of the present disclosure.

FIG. 3 is a general design scheme for a photoactive composition of matter of some embodiments of the present disclosure for use as a DSSC dye or BHJ semiconductor.

FIG. 4 is a chemical structure for the compound (Z)-2-cyano-3-[9,9′-diethyl-7-(N-phenylanilino)fluoren-2-yl]prop-2-enoic acid according to some embodiments of the present disclosure.

FIG. 5 is a chemical structure for 2-[[9,9′-diethyl-7-(N-phenylanilino)fluoren-2-yl]methylene]propanedinitrile according to some embodiments of the present disclosure

FIG. 6 depicts an exemplary method for designing photoactive compounds according to some embodiments of the present disclosure.

FIG. 7 is a chemical structure for (E)-2-cyano-3-[9,9-diethyl-7-[N-(2-naphthyl)anilino]fluoren-2-yl]prop-2-enoic acid according to some embodiments of the present disclosure.

FIG. 8 is a chemical structure for (E)-2-cyano-3-[9,9-diethyl-7-[N-(1-naphthyl)anilino]fluoren-2-yl]prop-2-enoic acid.

FIG. 9 is a graph containing data derived from computations carried out by molecular modeling software, and which shows the LUMO and HOMO values, in eV, of (E)-2-cyano-3-[9,9-diethyl-7-[N-(2-naphthyl)anilino]fluoren-2-yl]prop-2-enoic acid versus (E)-2-cyano-3-[9,9-diethyl-7-[N-(1-naphthyl)anilino]fluoren-2-yl]prop-2-enoic acid.

FIG. 10 is a chemical structure for (E)-2-cyano-3-[9,9-dihexyl-7-[N-(2-naphthyl)anilino]fluoren-2-yl]prop-2-enoic acid according to some embodiments of the present disclosure.

FIG. 11 is an illustration of molecular stacking that results from the presence of aromatic hydrocarbons according to some embodiments of the present disclosure.

FIG. 12 is an illustration of intermolecular spacing achieved through the addition of one or more alkyl tails to molecules comprising aromatic hydrocarbons, according to some embodiments of the present disclosure.

FIG. 13 is a depiction of the alignment of dye molecules on TiO₂ surface.

FIG. 14A is a space-filling model of (E)-2-cyano-3-[9,9-diethyl-7-[N-(2-naphthyl)anilino]fluoren-2-yl]prop-2-enoic acid, according to some embodiments of the present disclosure.

FIG. 14B is a space-filling model of (E)-2-cyano-3-[9,9-dihexyl-7-[N-(2-naphthyl)anilino]fluoren-2-yl]prop-2-enoic acid, according to some embodiments of the present disclosure.

FIG. 15 is an illustration of DSSC design depicting various layers of the DSSC according to some embodiments of the present disclosure.

FIG. 16 is another illustration of DSSC design depicting various layers of the DSSC according to some embodiments of the present disclosure.

FIG. 17 is a chemical structure for (E)-2-cyano-3-[9,9-diethyl-7-[2-naphthyl(phenyl)phosphanyl]fluoren-2-yl]prop-2-enoic acid according to some embodiments of the present disclosure.

FIG. 18 is a chemical structure for (E)-2-cyano-3-[9,9-diethyl-7-(2-naphthylsulfanyl)fluoren-2-yl]prop-2-enoic acid according to some embodiments of the present disclosure.

FIGS. 19A-C illustrate chemical structures for (E)-2-cyano-3-[9,9′-R,R′-7-[N-(2-naphthyl)aniline]fluoren-2-yl]prop-2-enoic acid, where R signifies a dialkyl tail of various isomers of C₂ to C₁₀ compounds, according to some embodiments of the present disclosure.

FIGS. 20A-F illustrate chemical structures for various embodiments of the present disclosure, labeled T2, T3, T4, T5, T6, and T7.

FIG. 21 is a graph containing data derived from computations carried out by molecular modeling software, and which shows HOMO and LUMO values of T2, T3, T4, and T5 of FIG. 20.

FIG. 22 is a graph containing data derived from computations carried out by molecular modeling software, and which shows HOMO and LUMO values of T6 and T7 of FIG. 20.

FIG. 23 is an example synthetic pathway for the formation of (Z)-2-cyano-3-[9,9′-diethyl-6-[N-(2-naphthyl)aniline]fluoren-3-yl]prop-2-enoic acid, according to some embodiments of the present disclosure.

FIG. 24A is an example illustration of DSSC design according to some embodiments of the present disclosure.

FIG. 24B is an example illustration of BHJ device design according to some embodiments of the present disclosure.

FIG. 25 is a representation of relative energy levels in eV of various components of an exemplar DSSC system that uses an iodide electrolyte according to some embodiments of the present disclosure. The data of FIG. 25 is derived from empirical results such as cyclic voltammetry or ultraviolet photoelectron spectroscopy.

FIG. 26 is a schematic view of a typical photovoltaic cell including an active layer according to some embodiments of the present disclosure.

FIG. 27 is an exploded, representational view of a sample PV cell having a transparent conducting electrode, an electron blocking layer, a p-type thin film active layer, an n-type organic active layer, a hole blocking layer, and a low work-function layer according to some embodiments of the present disclosure.

FIG. 28 is a schematic of a typical solid state DSSC device according to some embodiments of the present disclosure.

FIG. 29 is a representation of relative energy levels in eV of various components of an exemplar solid state DSSC system that uses a solid-state layer in accordance with some embodiments of the present disclosure. The data of FIG. 29 is derived from empirical results such as cyclic voltammetry or ultraviolet photoelectron spectroscopy.

FIG. 30 is a representation of relative energy levels in eV of various components of another exemplar solid state DSSC system that uses a solid-state layer in accordance with some embodiments of the present disclosure. The data of FIG. 30 is derived from empirical results such as cyclic voltammetry or ultraviolet photoelectron spectroscopy.

FIG. 31A is a chemical structure for (E)-2-cyano-3-[6-[9,9-diethyl-7-(4-methoxy-N-(4-methoxyphenyl)anilino)fluoren-2-yl]benzothiophen-2-yl]prop-2-enoic acid.

FIG. 31B is a chemical structure for (E)-2-cyano-3-[7-[7-(naphthalen-2-yl(phenyl)amino)dibenzo[b,d]thiophen-3-yl]benzo[c][1,2,5]thiadiazol-4-yl]acrylic acid.

FIG. 31C is a chemical structure for (E)-2-cyano-3-[5-[7-(naphthalen-2-yl(phenyl)amino)dibenzo[b,d]thiophen-3-yl]thieno93,2-b]thiophen-2-yl]acrylic acid.

FIG. 31D is a chemical structure for (E)-2-cyano-3-[4,4-diethyl-6[7-(naphthalen-2-yl(phenyl)amino)dibenzo[b,d]thiophen-3-yl]-4H-cyclopenta[1,2-b:5,4-b′]dithiophen-2-yl]acrylic acid.

FIG. 31E is a chemical structure for (E)-2-cyano-3-[5-[7-(4-methoxy-N-(4-methoxyphenyl)anilino)dibenzothiophen-3-yl]thiazol-2-yl]prop-2-enoic acid.

FIG. 31F is a chemical structure for (E)-2-cyano-3-[5-[2-(4-methoxy-N-(4-methoxyphenyl)anilino)quinoxalino[3,2-b]quinoxalin-8-yl]thiazol-2-yl]prop-2-enoic acid.

FIG. 31G is a chemical structure for (E)-2-cyano-3-[5-[9,9-diethyl-7-[N-(2-naphthyl)anilino]fluoren-2-yl]thiazol-2-yl]prop-2-enoic acid.

FIGS. 31H-O are a compilation of chemical structures for various nitrogen heterocycle compounds in accordance with some aspects of the present disclosure.

FIG. 32 is a depiction of interspersion of nanoparticles of p-type semiconducting material within a photovoltaic cell, according to some embodiments of the present disclosure.

FIG. 33 is a depiction of differences in resistance to charge recombination effects in various PVs according to some embodiments of the present disclosure.

FIG. 34 shows images of asphaltene thin films heated in air to approximately 300° C. and approximately 400° C., respectively.

FIG. 35 is a depiction of a process for treating asphaltene for use as an interfacial layer in accordance with some embodiments of the present disclosure.

FIG. 36 is a depiction of components of an exemplar hybrid PV battery according to some embodiments of the present disclosure.

FIG. 37 is a stylized diagram illustrating components of an exemplar PV device according to some embodiments of the present disclosure.

FIG. 38A is a stylized diagram illustrating a hybrid PV battery according to some embodiments of the present disclosure.

FIG. 38B is an electrical equivalent diagram relating to a hybrid PV battery according to some embodiments of the present disclosure.

The patent or application file contains at least one drawing executed in color. Copies of this patent or patent application publication with color drawing(s) will be provided by the Office upon request and payment of the necessary fee.

### DETAILED DESCRIPTION OF PREFERRED EMBODIMENTS

An emerging sector of PV technologies is based on organic materials which act as light absorbers and semiconductors in lieu of legacy materials like silicon. Organic electronics promise flexible, robust devices that can be fabricated cheaply by methods such as roll-to-roll printing. This has been demonstrated to date industrially with organic light-emitting diodes common today in mobile devices. Recent strides in Organic PV (“OPV”) technologies have reached performance levels approaching that of their inorganic, legacy counterparts; however, the cost of the specialty chemicals utilized as light-absorbers and semiconductors, such as Ruthenium-based dyes, has been prohibitive in bringing OPVs to market.

In addition, improvements in other aspects of PV technologies compatible with organic, non-organic, and/or hybrid PVs promise to further lower the cost of both OPVs and other PVs. For example, some solar cells, such as solid-state dye-sensitized solar cells, may take advantage of novel cost-effective and high-stability alternative components, such as hole-transport materials (or, colloquially, “solid state electrolytes”). In addition, various kinds of solar cells may advantageously include interfacial and other materials that may, among other advantages, be more cost-effective and durable than conventional options currently in existence.

The present disclosure relates generally to compositions of matter, apparatus and methods of use of materials in photovoltaic cells in creating electrical energy from solar radiation. More specifically, this disclosure relates to photoactive and other compositions of matter, as well as apparatus and methods of use and formation of such compositions of matter, as well as methods for designing photoactive compositions of matter.

These compositions of matter may include, for example, photoactive organic compositions of matter, hole-transport materials, and/or materials that may be suitable for use as, e.g., interfacial layers, dyes, and/or other elements of PV devices. Such compounds may be deployed in a variety of PV devices, such as heterojunction cells (e.g., bilayer and bulk), hybrid cells (e.g., organics with CH₃NH₃PbI₃, ZnO nanorods or PbS quantum dots), and DSSCs (dye-sensitized solar cells). The latter, DSSCs, exist in three forms: solvent-based electrolytes, ionic liquid electrolytes, and solid-state hole transporters. Some or all of these compositions may also advantageously be used in any organic or other electronic device, with some examples including, but not limited to: batteries, field-effect transistors (FETs), light-emitting diodes (LEDs), non-linear optical devices, memristors, capacitors, rectifiers, and/or rectifying antennas. The present disclosure further provides methods for designing some of the compositions of matter, in some embodiments allowing tunability of the compositions to obtain desirable characteristics in different applications.

In some embodiments, the petroleum by-product “asphaltenes” provides a desirable source of materials for design and synthesis of some compounds of the present disclosure. For example, asphaltenes may provide an ideal interfacial layer for use in various devices such as PVs and others discussed to herein. In some embodiments, asphaltenes may directly be used to form an interfacial layer by treatment alone, thereby bypassing potentially expensive extraction processes. The asphaltenes used in some embodiments of the present disclosure may be characterized as a portion of crude oil that is n-heptane insoluble and/or toluene soluble.

Asphaltenes may also provide a suitable source for various photoactive compounds of the present disclosure. Asphaltenes are rich in aromatic complexes, yet cheap and abundant, making them in some cases an ideal source for such photoactive materials. Of the myriad of chemical compounds contained within asphaltenes, several are of particular interest in the synthesis of light-absorbing and other molecules for use in PV and other electric devices including heterojunction, hybrid, and DSSC PVs, as well as batteries, FETs, LEDs, non-linear optical devices, memristors, capacitors, rectifiers, and/or rectifying antennas. Thus, in some embodiments, the compositions of the present disclosure may be derived from materials extracted or otherwise obtained from asphaltene, such as fluorenes, naphthalenes, benzothiophenes, dibenzothiophenes, naphthothiophenes, dinaphthothiophenes, benzonaphthothiophenes, benzenes, benzothiazoles, benzothiadiazoles, cyclopentabisthiophenes, and thienothiophenes. Nonetheless, the flexibility of the design and tunability of some of the photoactive compositions of the present disclosure allows for a wide variety of potential sources of materials consistent with the present disclosure, including but not limited to asphaltenes.

In some embodiments, the present disclosure provides uses of photoactive and other compositions of matter in PV devices including heterojunction cells, hybrid cells, and DSSCs. In embodiments concerning DSSCs, said photoactive compositions are compatible with traditional solvent-based electrolytes of I₂ or Co complexes, but additionally solid-state DSSC structures free of electrolyte, containing rather hole-transport materials such as spiro-OMeTAD, CsSnI₃, Cu₂O, and other active materials. The photoactive compositions of matter of some embodiments may be used in any organic electronic device, including but not limited to batteries, field-effect transistors (FETs), light-emitting diodes (LEDs), and non-linear optical devices, memristors, capacitors, rectifiers, and/or rectifying antennas. The photoactive compositions of matter may, in some embodiments, be employed with additives (such as, in some embodiments, chenodeoxycholic acid or 1,8-diiodooctane).

In some embodiments, the present disclosure provides small-molecule photoactive compositions of matter. In some embodiments, the compositions of matter may be based upon polymeric or oligomeric materials. As used herein, “small-molecule” or “small molecule” refers to a finite molecular structure (e.g., acetone or benzene). It could, in some cases, also be referred to as a monomeric unit.

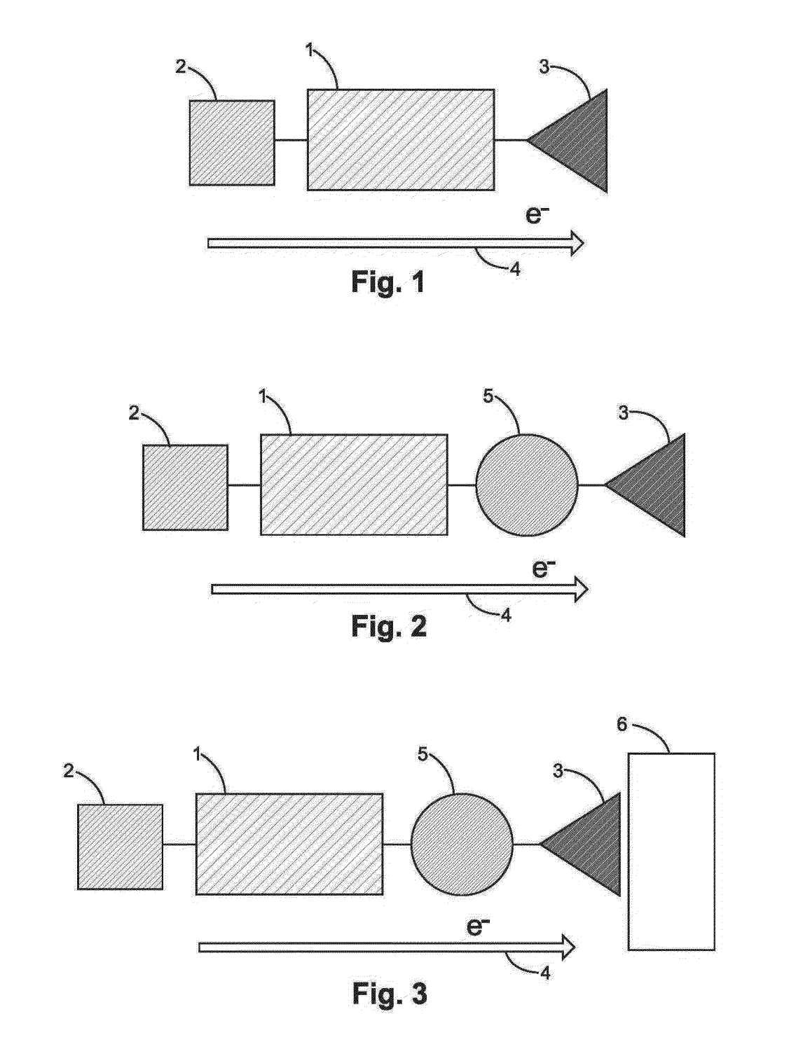

Referring to FIG. 1, in some embodiments, the compositions of matter in accordance with some embodiments of the present disclosure generally include: a primary electron donor moiety 2 a core moiety 1, and an electron withdrawing moiety 3. In some embodiments, the primary electron donor moiety 2 is chemically bound to the core moiety 1, and the core moiety is chemically bound to the electron-withdrawing moiety 3. In some embodiments, the electron donor moiety is located on the opposing end of the photosensitive compound from the electron-withdrawing moiety. In some embodiments, electrons generally flow within the photoactive composition from the primary electron donor moiety, to the core moiety, to the second electron donor moiety (if present), to the electron-withdrawing moiety, in accordance with the electron flow 4 depicted in FIGS. 1, 2, and 3.

In some embodiments, the compositions of matter optionally may further comprise a second electron donor moiety 5, as shown in FIG. 2. In some embodiments, the primary electron donor moiety 2, core moiety 1, and electron withdrawing moiety 3 may be bonded to each other in the order shown in FIG. 1. In other embodiments, the second electron donor moiety 5 may be between the core moiety 1 and the electron-withdrawing moiety 3, as shown in FIG. 2. And in some embodiments, the electron-withdrawing moiety 3 may comprise a substituent capable of binding the photoactive composition to another substance 6, as shown in FIG. 3. In some embodiments, this substance 6 may be a mesoporous layer of a DSSC (which may be, for example, TiO₂). In some embodiments, the compositions of matter may comprise a second electron-withdrawing moiety instead of or in addition to a second electron donor moiety. In yet other embodiments, the composition may comprise three or more electron-withdrawing moieties bonded to each other. In some embodiments, each electron-withdrawing moiety may instead be located anywhere in the composition.

As used herein, “moiety” refers to the most general term to identify a molecular fragment (e.g., tri-aryl amine). It may include, but not necessarily be limited to, a substituent and/or a functional group. A “substituent” is any partial, identifiable fragment bonded (covalently, ionically, or otherwise) to a parent molecule (e.g., a methyl group), and a “functional group” is a molecular group that may be used to define the parent molecule (e.g., carboxylic acid). Thus, a substituent may include, but not necessarily be limited to, a functional group, and vice-versa. In addition, electron donor and electron-withdrawing moieties may generally be referred to as electron-rich and electron-poor, respectively.

In some embodiments, the present disclosure provides a photovoltaic device comprising: a first electrode; an active layer comprising a first active material that comprises a copper-oxide compound, a second active material, and a dye; and a second electrode; wherein the active layer is between the first and second electrodes; and wherein the dye comprises an organic compound comprising: a primary electron donor moiety; a core moiety; and an electron-withdrawing moiety. In some embodiments, the primary electron donor moiety may comprise at least one substituent selected from the group consisting of: aryl amine, aryl phosphine, aryl arsine, aryl stibine, aryl sulfide, aryl selenide, phenyl, phenol, alkoxy phenyl, dialkoxy phenyl, alkyl phenyl, phenol amine, alkoxy phenyl amine, dialkoxy phenyl amine, alkyl phenyl amine, and combinations thereof; the core moiety may comprise at least one aryl substituent selected from the group consisting of: fluorene, nitrogen heterocycle, benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene, benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof; and the electron-withdrawing moiety may comprise at least one substituent selected from the group consisting of: a carboxylic acid, a monocyanocomplex, a dicyanocomplex, a thiocyanocomplex, an isothiocyanocomplex, and combinations thereof.

In some embodiments, the present disclosure provides a photovoltaic device comprising: a first electrode; an active layer comprising a first active material, a second active material, a dye, and a thin-coat interfacial layer; and a second electrode; wherein the active layer is between the first and second electrodes; and wherein the dye comprises an organic compound comprising: a primary electron donor moiety; a core moiety; and an electron-withdrawing moiety. In some embodiments, the primary electron donor may comprise at least one substituent selected from the group consisting of: aryl amine, aryl phosphine, aryl arsine, aryl stibine, aryl sulfide, aryl selenide, phenyl, phenol, alkoxy phenyl, dialkoxy phenyl, alkyl phenyl, phenol amine, alkoxy phenyl amine, dialkoxy phenyl amine, alkyl phenyl amine; and combinations thereof; the core moiety may comprise at least one aryl substituent selected from the group consisting of: fluorene, nitrogen heterocycle, benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof; and the electron-withdrawing moiety may comprise at least one substituent selected from the group consisting of: a carboxylic acid, a monocyanocomplex, a dicyanocomplex, a thiocyanocomplex, an isothiocyanocomplex, and combinations thereof.

In some embodiments, the present disclosure provides a photovoltaic device comprising: a first electrode; an active layer comprising a first active material, a second active material, a dye, and a thin-coat interfacial layer comprising a bilayer comprising titania and alumina; and a second electrode; wherein the active layer is between the first and second electrodes; and wherein the thin-coat interfacial layer is coated onto at least a portion of either of the first active layer and the second active layer.

Molecular Tunability and Composition Design

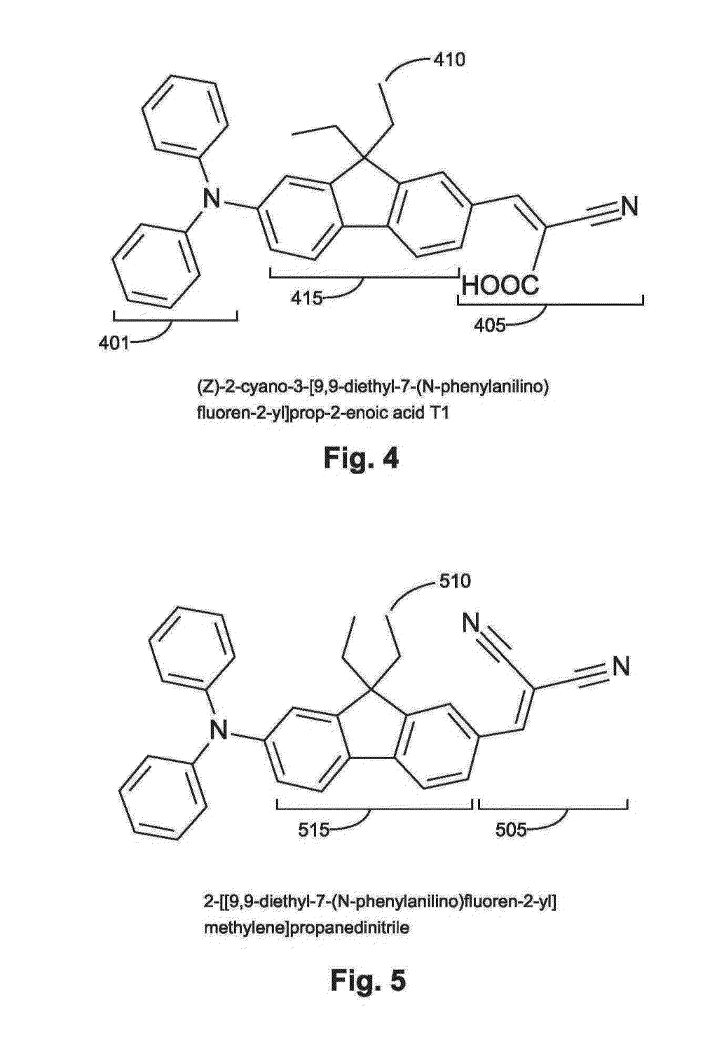

In some embodiments, the core moiety 1 intrinsically has all necessary characteristics to be employed in the various applications of the photoactive compositions of the present disclosure, such as a dye for a DSSC, or as a LED, or in any other application consistent with this disclosure as laid out previously. The photoactive compositions of these embodiments comprise the additional components identified in FIG. 1 (that is: a primary electron donor moiety 2, one or more electron withdrawing moieties 3, and, in some embodiments, an optional second electron donor moiety 5) in order to enhance or otherwise modify the intrinsic characteristics of the core moiety 1. These compositions, in some embodiments, further comprise one or more alkyl tails (for example, the 9,9-diethyl moieties 410 appended to the fluorene moiety 415 of FIG. 4 are alkyl tails of one embodiment, as are the 9,9-diethyl moieties 510 appended to the fluorene moiety 515 of FIG. 5). These additional components (primary and second electron donor moieties, electron withdrawing moiety, and alkyl tail or tails) may in some embodiments provide for a high degree of molecular tunability, allowing each composition of these embodiments to be finely tuned to its application, including obtaining desired properties relating to the composition's electronic properties, which include, but are not limited to: absorption window, molecular orbital energy levels (including band gap E_{g}, HOMO (Highest Occupied Molecular Orbital) and LUMO (Lowest Unoccupied Molecular Orbital) energy levels), and adjustment of intermolecular interactions such as intermolecular spacing. In some embodiments, selection and incorporation of these additional components may provide or affect additional electronic properties or other characteristics, such as the capability of bonding to another surface, molar absorptivity, modifying the molecular dipole, electron-donating and withdrawing capabilities, and generation and maintenance of excitons, among others. As used herein, “electronic properties” include any property or characteristic of a molecule that one of ordinary skill in the art would recognize as affecting or otherwise modifying a molecule's electronic, photoactive, conducting, dielectric or semiconducting characteristics.

Accordingly, some embodiments of the present disclosure provide methods for designing a photoactive composition comprising sourcing a core moiety, and further comprising selection of the additional components so as to tune the composition by enhancing the electronic properties of the photoactive composition as compared to the electronic properties of the core moiety alone.

The methods of selection of some embodiments comprise selecting components based upon one or more tunability considerations. Tunability considerations may, in some embodiments, comprise any one or more electronic properties. Non-limiting examples of such properties of the photoactive composition sought to be designed include: HOMO (Highest Occupied Molecular Orbital) energy level; LUMO (Lowest Unoccupied Molecular Orbital) energy level; band gap (E_{g}), which is the difference between HOMO and LUMO energies; absorption window (i.e., the allowed absorption wavelengths based on the band gap E_{g}); addition of semiconducting or conducting characteristics to the photoactive composition; polarizability; molar absorptivity; intermolecular spacing of the photoactive composition; oxidation susceptibility; reduction susceptibility; chiralty or achiralty; exciton formation; exciton maintenance; molecular dipole moment; heat of solvation; structural volume; heat of formation; V_{OC} (open-circuit voltage); J_{SC} (Photocurrent density); Fill Factor percentage (FF %); and light-to-power conversion efficiency (PCE). Tunability considerations may, in some embodiments, further or instead comprise any other electronic property or properties of the photoactive composition sought to be designed. Although several such properties are expressly mentioned herein, one of ordinary skill in the art with the benefit of this disclosure would be capable of taking into account any other electronic property or properties in tunability considerations.

Tunability considerations of some embodiments may in addition or instead comprise any one or more of various conditions in the environment in which the photoactive composition is used or intended to be used. Such environmental conditions may, in some embodiments, comprise any one or more of the following: the presence of a solvent; the identity of the solvent (if present); the concentration of the photoactive composition in solution with a solvent (if present); the presence of a surface or other substance to which the photoactive composition is or is intended to be bonded, absorbed, adsorbed, or otherwise chemically or physically attached to a surface (such as, in some embodiments, TiO₂); the presence of additives (such as, in some embodiments, chenodeoxycholic acid or 1,8-diiodooctane).

Tunability considerations may be taken into account in the methods of some embodiments in various ways. In some embodiments, in order to modify the core moiety intrinsic characteristics, the additional components are selected for addition to the core moiety via covalent bonding in order to produce a photoactive composition with enhanced or otherwise modified properties. In some embodiments, to make the photoactive composition easier to oxidize and more difficult to reduce, electron-donating moieties are selected for addition to the composition; this can also, in some embodiments, induce p-type semiconducting character. Further, in some embodiments, one or more electron-withdrawing moieties are selected for addition in order to make the composition more difficult to oxidize and easier to reduce; this can also, in some embodiments, induce n-type semiconducting character. In other embodiments, electron-donating and electron-withdrawing moieties, 2 and 3, respectively, can be selected for addition together on opposite ends of the composition, as in FIG. 1, to fine-tune the molecular electronic characteristics beyond what either moiety can do alone. For example, a smaller band gap E_{g} may result from addition of both an electron-donating and electron-withdrawing moiety than would result from the presence of only one of those two components. Additionally, in some embodiments, the motif illustrated in FIG. 1 can be designed to create a molecular dipole 4 of desired magnitude and direction (molecular dipoles are vector quantities). Further, in other embodiments, moieties such as alkyl chains, carboxylic acid groups, or aromatic groups can be selected and added to induce molecular ordering on a surface, such as Au, Ag, FTO (fluorine-doped tin oxide), ITO (indium tin oxide), Nb₂O₅ or TiO₂, as a layer or into supramolecular extended structures, such as metal organic frameworks, covalent organic frameworks, or crystalline structures.

Tunability considerations are taken into account in the design methods of other embodiments in order to maximize or otherwise alter the electronic properties of the photoactive composition. For instance, in some embodiments, it is desirable to minimize the band gap (E_{g}), which as noted above is the energy difference between the HOMO energies and the LUMO energies, in order to red shift the light absorption maximum and therefore achieve increased current in the photoactive composition through a broader spectral window. In some embodiments, this may comprise creating a deeper (that is, greater absolute value in eV) LUMO level energy, for example to facilitate electron transfer from an electron donor or electrode. In other embodiments, a deeper HOMO is desired, for example to allow unimpeded hole transfer to another semiconducting material or to an electrode. In some embodiments, it is beneficial to have a shallower LUMO energy, for example to allow electron transfer to an electron accepting material or electrode. In other embodiments, it is beneficial to have a shallower HOMO energy, for example to facilitate the acceptance of a hole from a semiconducting material or electrode.

The methods of other embodiments may comprise tuning the composition's band gap E_{g}, its absorption window, or both, by selecting and/or incorporating any one or more of the following into the composition: a primary electron donor moiety, a second electron donor moiety, an electron-withdrawing moiety, and a second electron-withdrawing moiety. The methods of yet other embodiments may comprise selecting and/or incorporating more than two of either or both of electron donor moieties and electron-withdrawing moieties. Any one or more other tunability considerations may also or instead be accounted for by selecting and/or incorporating any one or more of the primary electron donor moiety, second electron donor moiety, and electron-withdrawing moiety. The methods of some embodiments may further comprise tuning the composition's intermolecular interactivity by selecting and incorporating one or more alkyl tails. The methods of other embodiments may comprise tuning the composition's intermolecular interactivity by selecting and incorporating any one or more of the core moiety or any additional component. For example, in some embodiments, carboxylic acids may cause molecules of the photoactive composition to dimerize. In other embodiments, for example, a primary electron donating moiety comprising an anthracene moiety instead of a naphthyl moiety may increase the attraction between two molecules of the photoactive composition.

Selection of one or more electron donor moieties and/or electron-withdrawing moieties may, in some embodiments, be carried out in order to alter the band gap E_{g} of the photoactive composition. This may be accomplished, for example, by modifying either or both of the HOMO or LUMO. For example, in some embodiments, a shallower HOMO (that is, greater electron density) for the photoactive composition as a whole is desirable. In such embodiments, a primary electron donor moiety that is selected and incorporated into the photoactive composition may comprise any one or more of the following: alkyl amines, alkyl aryl amines, and aryl amines. The primary electron donor moieties of other embodiments may be selected and incorporated such that they comprise any one or more of the following: anisole aryl amines, including other alkoxy derivatives greater than methyl, di- and tri-alkyl derivatives; alkyl and other hydrocarbon phenyl substituents; halogen substituents; and either p-, o-, or m-covalent bonding. In other embodiments, the electron-withdrawing moiety may be selected and incorporated in order to adjust the LUMO. For example, in order to make the LUMO very shallow, a strong electron-withdrawing moiety (that is, an electron-withdrawing group with a greater electron affinity relative to other moieties of the photoactive composition) should be selected. Examples of strong electron-withdrawing moieties include any one or more of the following: dicyanomethane, cyano acrylate, dicarboxylic acid, as well as halogen acrylates. Weaker electron-withdrawing moieties (that is, electron-withdrawing moieties that would make the LUMO less shallow) include, but are not limited to, any one or more of the following: carboxylic acid, amides, esters, and halogenated hydrocarbons. In some embodiments wherein alteration of the E_{g} is desired (by, for example, making E_{g} smaller), alteration of only one of the LUMO or HOMO energy level may be targeted. In some embodiments, various tunability considerations may be inter-dependent (that is, at least one tunability consideration may depend on at least one other tunability consideration).

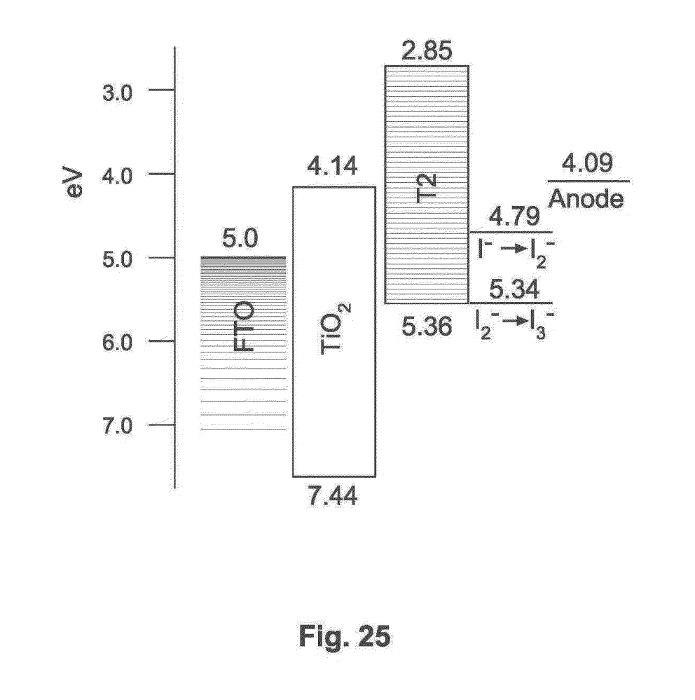

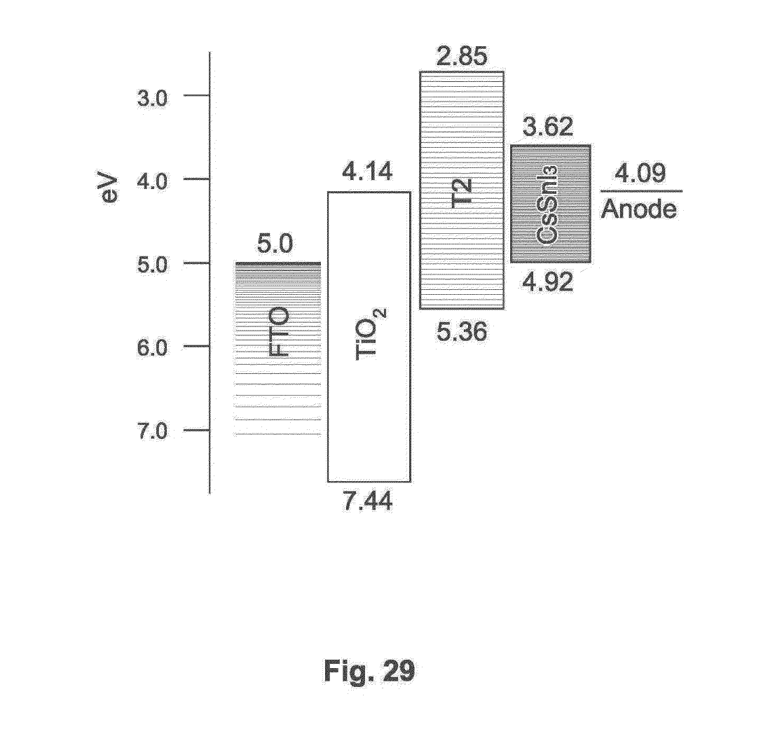

The following example illustrates the interplay and specificity of the tunability considerations of some embodiments. FIG. 25 is a representation of relative energy levels in eV of various components of an exemplar DSSC system that uses an iodide electrolyte: FTO (fluorine-doped tin oxide); TiO₂ (titanium dioxide); T2 (an embodiment of a photoactive compound of the present disclosure); iodide electrolyte (illustrated by oxidation reactions I⁻→I₂⁻ and I₂⁻→I₃⁻); and the Anode. The data shown in FIG. 25 was derived from empirical results such as cyclic voltammetry or ultraviolet photoelectron spectroscopy. In FIG. 25, relative conduction band and LUMO energy values of TiO₂ and T2 (4.14 and 2.85, respectively) are toward the top of the graph, and valence band and HOMO energy values are toward the bottom (7.44 and 5.36, respectively), with eV values of iodide electrolyte reduction of T2 and eV values at the anode and FTO also being shown. The T2 is employed in this example embodiment as a DSSC dye. As can be seen in FIG. 25, shallower HOMO energies in T2 would not allow for reduction of the oxidized T2 by the I₂⁻→I₃⁻ couple, so a shallower HOMO energy level would not be desired. However, a deeper LUMO energy level would result in a reduction in E_{g} in the T2, which could in some embodiments lead to a greater PCE. Thus, the nature of the application in which the photoactive composition is deployed may provide additional tunability considerations, demonstrating in this example that modification of the design of T2 should target deeper LUMO energy levels but not shallower HOMO energy levels. In other instances—such as use in a solid-state DSSC in accordance with some embodiments of the present disclosure—the photoactive compound may be designed to target shallower HOMO energy levels due to the presence of, for example, a solid electrolyte (as opposed to a liquid electrolyte such as the iodide electrolyte depicted in FIG. 25). FIG. 29, for example, shows the shallower HOMO energy level of a solid electrolyte of some embodiments (CsSnI₃), which permits a photoactive compound of the present disclosure (e.g., T2, as shown in FIGS. 25 and 29) to be designed with a shallower HOMO. Thus, the use of a solid electrolyte could, in some embodiments, open greater design possibilities and permit targeting a shallower HOMO energy level (and therefore, in some embodiments, an even smaller E_{g}). This could provide significant advantages in the PCE values of solid state DSSCs employing a photoactive composition of matter according to the present disclosure. FIG. 29 and solid-state DSSC embodiments are discussed in greater detail elsewhere in this disclosure.

In some embodiments, selection of any one or more of the primary electron donor moiety, the second electron donor moiety, and the electron-withdrawing moiety may have effects on the overall photovoltaic power conversion efficiency (PCE) of the photoactive composition when used in, for example, OPV applications. In some embodiments, it may be desirable to design the composition so as to maximize its PCE when used in OPV applications. The effects on the PCE of various design elements alone or in combination with other design elements may not be readily determinable without calculation and experimentation. Thus, the present disclosure further provides, in some embodiments, a method for carrying out the necessary experimentation and calculation to optimize selection of any one or more of: the core moiety, the electron-withdrawing moiety, the primary electron donor moiety, and the second electron donor moiety. Therefore, such calculation and experimentation would be routine to one of ordinary skill in the art with the benefit of this disclosure.

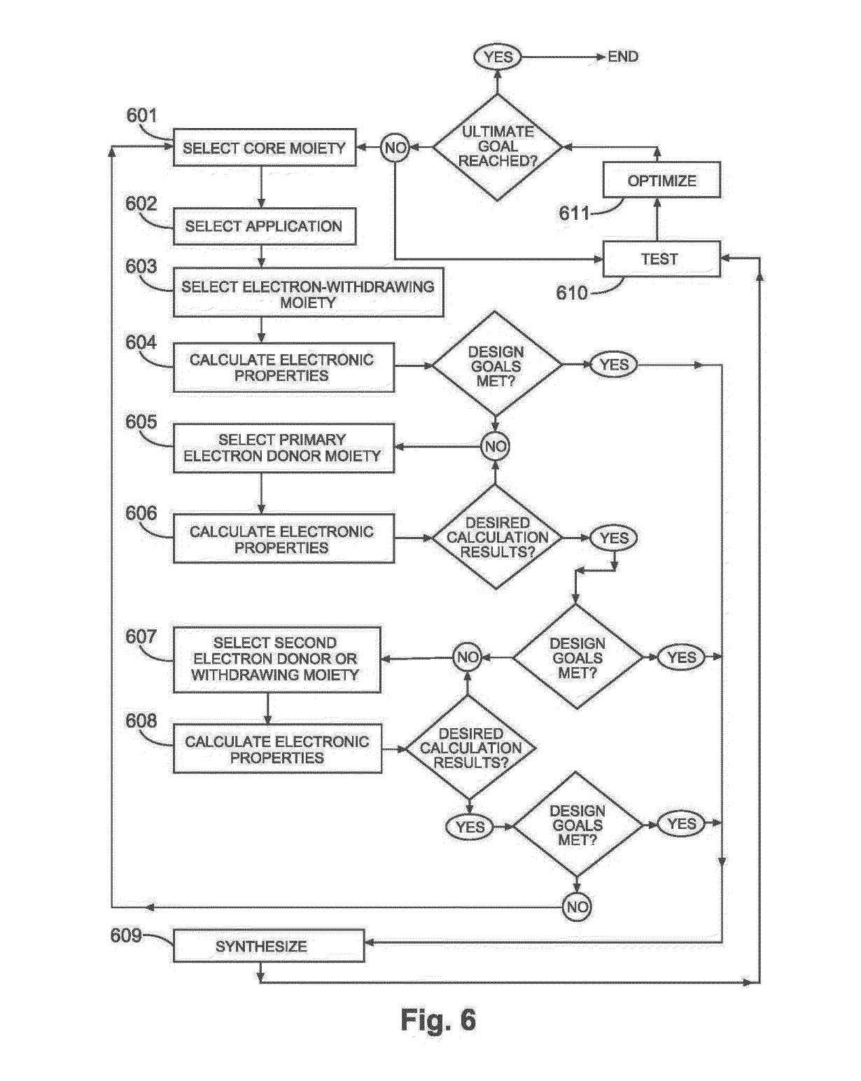

Referring to FIG. 6, this method, in some embodiments, may comprise a photoactive core moiety selection step 601. In some embodiments, this step 601 may further comprise selecting a photoactive core moiety from asphaltenes. Thus, for example, a range of potentially useful core moieties selected from asphaltenes may include, but not necessarily be limited to, any one or more of the following: fluorene, benzothiophene, dibenzothiophene, naphthothiophene, dinaphthiophene, and benzonaphthothiophene.

In other embodiments, the method may further comprise an application selection step 602 comprising, in some embodiments, determining one or more applications for the photoactive composition (e.g., BHJ, DSSC, FET). In some embodiments, the method may further comprise an electron-withdrawing moiety selection step 603. In some embodiments, the electron-withdrawing moiety is selected based at least in part upon the application selected at 602. For example, in embodiments wherein DSSC is selected at 602, it may be desirable to select an electron-withdrawing moiety that comprises a carboxylic acid substituent, which may enable bonding to another surface, examples of which include, but are not limited to, Au, Ag, FTO (fluorine-doped tin oxide), ITO (indium tin oxide), Nb₂O₅, or TiO₂ as a layer or into supramolecular extended structures, such as metal organic frameworks, covalent organic frameworks, or crystalline structures. In other embodiments, an electron-withdrawing moiety comprising a cyanoacrylate, boronic acid, sulfate, phosphate, nitrate, halogen silane, or alkoxy silane may be selected to enable surface bonding. Furthermore, in some embodiments, notwithstanding the depiction of FIG. 6, the application selection step 602 may be carried out prior to the core moiety selection step 601.

In some embodiments, the method may further comprise a first electronic property calculation step 604, which may comprise calculating the electronic properties of a composition comprising the core moiety selected at step 601 and the electron-withdrawing moiety selected at step 603. Electronic properties calculated in this step may, in some embodiments, include the electronic properties previously discussed and which are calculable. Thus, in some embodiments, electronic properties calculated in this step may comprise any one or more of the following: HOMO structure, LUMO structure, HOMO energy, LUMO energy, band gap E_{g}, molar absorptivity, allowed absorption wavelengths, intermolecular spacing, molecular dipole, heat of solvation, structural volume, and heat of formation. In some embodiments, other electronic properties already discussed may also be calculated in this step.

In some embodiments, the method may further comprise a primary electron donor moiety selection step 605, which in some embodiments may be based at least in part upon the result of the electronic property calculation step 604. In some embodiments, the primary electron donor is selected in order to modify the HOMO of the photoactive composition. In addition, the method of some embodiments may further comprise a second electronic property calculation step 606, which comprises calculating the electronic properties of the composition comprising the core moiety selected at step 601, the electron-withdrawing moiety selected at step 603, and the primary electron donor moiety selected at step 605.

This second electronic property calculation step 606 may, in some embodiments, be iteratively repeated in alternation with the primary electron donor moiety selection step 605, such that a different primary electron donor moiety is selected based at least in part upon the results of the second electronic property calculation step 606, followed by another iteration of the second electronic property calculation step 606, which may in some embodiments lead to again repeating the primary electron donor selection step 605. In some embodiments, this repetition continues until a desired result of the second electronic property calculation step 606 is reached. Desired results of the second electronic property calculation step may, in some embodiments, be based upon the tunability considerations previously discussed. Thus, returning to the example of minimizing the band gap (E_{g}) in order to red shift the light absorption maximum and therefore achieve increased current in the photoactive composition through a broader spectral window, a desired result would therefore comprise a minimized band gap E_{g} value. In some embodiments, the calculation results may furthermore indicate that overall design goals have been met, for example, by indicating a desired E_{g} value, PCE value, or other electronic property value has been obtained. If this is the case, the method may in some embodiments proceed directly to a synthesis step 609.

The method in some embodiments may comprise a second electron donor or withdrawing moiety selection step 607. This step may in some embodiments comprise selection of either or both of a second electron donor moiety or a second electron-withdrawing moiety. Results of the second electronic property calculation step 606 may, in some embodiments, form at least part of the basis for determining whether a second electron donor moiety, a second electron-withdrawing moiety, or both, should be selected at the second electron donor or withdrawing moiety selection step 607. Results of the second electronic property calculation step 606 may also or instead form at least part of the basis for determining which second electron donor moiety, second electron-withdrawing moiety, or both, should be selected. In addition, this step, in some embodiments, may further comprise a third electronic property calculation step 608, which comprises calculating the electronic properties of the composition comprising any component so far selected. Thus, in some embodiments, the calculation may be based upon a photoactive composition comprising any one or more of: the core moiety selected at step 601; the electron-withdrawing moiety selected at step 603; the primary electron donor selected at step 605; and the second electron donor moiety and/or second electron-withdrawing moiety selected at step 607.

This third electronic property calculation step 608 may, in some embodiments, be iteratively repeated in alternation with the second electron donor or withdrawing moiety selection step 607, such that a different second electron donor moiety, second electron-withdrawing moiety, or both, is selected based at least in part upon the results of the third electronic property calculation step 608, followed by another iteration of the third electronic property calculation step 608, which may in some embodiments lead to again repeating the second electron donor or withdrawing moiety selection step 607. In some embodiments, this repetition continues until a desired result of the third electronic property calculation step 608 is reached. As with the second electronic property calculation step 606, desired results of the third electronic property calculation step 608 may, in some embodiments, be based at least in part upon tunability considerations. Again, desired values may in some embodiments differ depending upon the tunability consideration and the target.

In some embodiments, the selection and calculation steps 601 and 603 through 608 may be carried out at least in part by using molecular modeling software. Non-limiting examples of molecular modeling software include Spartan, Jaguar, and Gaussian. Calculations are, in some embodiments, based on Density Functional Theory, method: RB3LYP, and basis set: 6-31G*.

The method of some embodiments may further comprise a synthesis step 609. In some embodiments, this step comprises synthesizing one or more molecules that comprise the component or components selected in any one or more of the previous steps 601, 603, 605, and 607. In some embodiments, this synthesis step 609 is carried out once any one or more of the first electronic property calculation step 604, the second electronic property calculation step 606, and the third electronic property calculation step 608 result in a desired value or set of values to meet the design goals of the photoactive composition. Design goals of the photoactive composition may include a desired value of any one or more electronic properties, which in some embodiments may depend at least in part upon the application selected for the composition at the application selection step 602. For example, in some embodiments, where the composition is to be used in a DSSC, a minimum desired PCE, such as, e.g., 7.5% may be a design goal. Other examples may include a maximum desired band gap, or a specific HOMO and/or LUMO energy level to allow compatible charge transfer with another substance. Design goals may also include, in some embodiments, simply the existence of a molecular dipole moment, and in some embodiments, that dipole moment may be of a desired minimum value.

The design goals may or may not be the same as the desired calculation results; thus, for example, a desired calculation result of a band gap below a desired maximum value (in eV) might not result in a molecule that, when applied to an OPV, would exhibit a minimum desired PCE value. Thus, in some embodiments, if, after steps 601 through 608 are performed and, although desired results of the third calculation step 608 are reached, design goals are not reached, then the method of these embodiments may further comprise repeating any one or more of steps 601 through 608 in accordance with the description of various embodiments above. For example, referring to FIG. 6, an embodiment is shown wherein, if design goals are not met even after the third electronic property calculation step 608 achieves desired results, the process repeats at the core moiety selection step 601.

In some embodiments, the method may further comprise a testing step 610 wherein, in some embodiments, the molecule or molecules are tested in the one or more applications selected at the application selection step 602.

In some embodiments, the method may further comprise an optimization step 611, wherein the device or application in which the photoactive composition is tested is optimized by various means. Such means include, but are not necessarily limited to, any one or more of the following: radiation, thermal or chemical treatments, or interfacial modification or additives. In some embodiments, optimization may comprise the addition of one or more alkyl tails to the photoactive composition. In some embodiments, the alkyl tails may be added to the core moiety of the photoactive composition.

In some embodiments, the method may further comprise repeating the testing step 610 following optimization step 611. In some embodiments, optimization step 611 and testing step 610 may be repeated one or more times until ultimate goals are met. In some embodiments, after zero or more repetitions of the alternating optimization step 611 and testing step 610 in this manner, if ultimate goals are still not met, the process repeats from the beginning.

Furthermore, the method of some embodiments may additionally comprise an alkyl tail selection step (not shown in FIG. 6) instead of or in addition to alkyl tail addition, if any, in optimization step 611. In some embodiments, this step may take place before synthesis step 609. In some embodiments, the alkyl tail selection step may comprise selecting any one or more alkyl tails to be appended to the composition. In some embodiments, the alkyl tail or tails may be selected for addition to the core moiety of the composition. Selection of an alkyl tail or tails may be based at least in part upon the calculation results of any one or more of electronic property calculation steps 604, 606, and 608. In some embodiments, the alkyl tail selection step may further comprise selecting the location on the composition at which to append the alkyl tail or tails. The alkyl tail selection step also may comprise an additional electronic property calculation step, which may be carried out similarly to any of electronic property calculation steps 606 and 608 (that is, iteratively calculating electronic properties, changing alkyl tail selection, and re-calculating electronic properties).

It will be apparent to one of ordinary skill in the art that the above-outlined methods are merely example embodiments. Various alterations are contemplated by this disclosure. Thus, although the example embodiment outlined in FIG. 6 proceeds with later calculations based upon a selected electron-withdrawing moiety at step 603, and contemplates selection of different primary electron donor moieties and second electron donor moieties depending upon results of later calculations, the method could instead proceed whereby a different electron-withdrawing moiety is selected when desired calculation results are not met in any of steps 604, 606, or 608.

The systems and methods of the present disclosure described above may be implemented in software to run on one or more computers, where each computer includes one or more processors, a memory, and may include further data storage, one or more input devices, one or more output devices, and one or more networking devices. The software includes executable instructions stored on a tangible medium.

Methods of various embodiments consistent with this disclosure are further elaborated in the context of the below discussion of various components of the compositions of matter of certain embodiments of the present disclosure.

Core Moiety

In some embodiments, the core moiety may comprise fluorene. In other embodiments, the core moiety may comprise any one of: benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene, benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof. In other embodiments, the core moiety may comprise any other multi-cyclic aromatic ring. In certain embodiments, the core moiety may comprise a nitrogen heterocyclic compound (e.g., the aforementioned pyrazine-, quinaxaline-, and thiazole-comprising moieties, in addition to any other nitrogen heterocycles, such as phenazines, purines, heterocyclic piperazine derivatives, heterocyclic pyridine derivatives, etc.). In some embodiments, the core moiety comprises a compound or compounds extracted from asphaltenes.

Alkyl Tails and Alkyl Tail Selection

In some embodiments, the core moiety may further comprise one or more alkyl tails. In some embodiments, an alkyl tail is a substituent comprising a carbon backbone and that is bonded to a single carbon atom of any of the following: a core moiety; a primary electron donor moiety; an electron donor moiety; and an electron-withdrawing moiety. In some embodiments, the distal end of the carbon backbone of the alkyl tail is not covalently bonded to another compound. In some embodiments, two alkyl tails are bonded to the same carbon atom. For example, in some embodiments in which the core moiety comprises fluorene, the core moiety may additionally comprise two alkyl tails appended at the 9,9′ carbon of the fluorene molecule (e.g., a 9,9′-dialkyl functionalized fluorene). By way of example, FIG. 4 depicts a composition of some embodiments of the present disclosure, which includes a fluorene 415 functionalized with diethyl alkyl tails 410 at the 9,9′ carbon of the fluorene. Similarly, the embodiment depicted in FIG. 5 includes a fluorene 515 functionalized with diethyl alkyl tails 510 at the 9,9′ carbon of the fluorene. Appending an alkyl tail or tails to the 9,9′ carbon of fluorene may be advantageous because the hydrogen atoms appended thereto are acidic, and may be more readily substituted by alkyl tails.

However, different advantages such as greater molecular spacing may be achieved by appending an alkyl tail or tails to different locations on the core moiety, or on different locations of the photoactive composition, depending upon the makeup of the photoactive composition. Thus, in some embodiments, the alkyl tail or alkyl tails appended to the photoactive composition of matter may be appended on any carbon of the core moiety in place of one or more hydrogen atoms (that is, the alkyl tail or tails replace a hydrogen or hydrogens bonded to the carbon). The alkyl tail or tails may, in other embodiments, be appended to any carbon, or other atom, bonded to one or more hydrogens within the photoactive composition of matter (e.g., a carbon, or other atom, of the substituent that constitutes the primary electron donor moiety of some embodiments). In yet other embodiments comprising multiple alkyl tails, the alkyl tails may be appended to different carbon, or other, atoms within the composition.

The alkyl tail or tails of some embodiments may comprise C₂ to C₁₀ hydrocarbons, including various isomers. The alkyl tails of other embodiments may comprise C₂ to C₁₅ hydrocarbons, or, in other embodiments, C₂ to C₂₀ hydrocarbons. In yet other embodiments, the alkyl tails may comprise C₂ to C₃₀ hydrocarbons, or, in other embodiments, C₂ to C₄₀ hydrocarbons. As used herein, a “C₂” hydrocarbon is a hydrocarbon containing 2 carbon atoms; a C₁₀ hydrocarbon is a hydrocarbon containing 10 carbon atoms, and, in general, a Cₓ hydrocarbon is a hydrocarbon containing x carbon atoms, where x is an integer. The alkyl tail or tails of some embodiments may comprise more than 40 carbons.

In some embodiments, the C₂ to C₁₀ hydrocarbons are linear or branched hydrocarbon chains. Thus, the alkyl tail or tails of some embodiments may comprise a C₂ to C₁₀ linear chain (that is, a hydrocarbon chain that is 2 through 10 carbon atoms long), with hydrocarbon branches of various lengths appended to various carbons on the C₂ to C₁₀ linear chain. Thus, when an alkyl tail of some embodiments comprises a C₄ hydrocarbon, those embodiments may comprise any of the various possible isomers of C₄ hydrocarbons. That is, a C₄ alkyl tail of some embodiments may comprise a butyl group, or it may comprise a branched alkyl tail such as a methylpropyl group. Again, various isomers of a methylpropyl group may be used in various embodiments (e.g., the methyl group may be appended to any carbon of the propyl group).

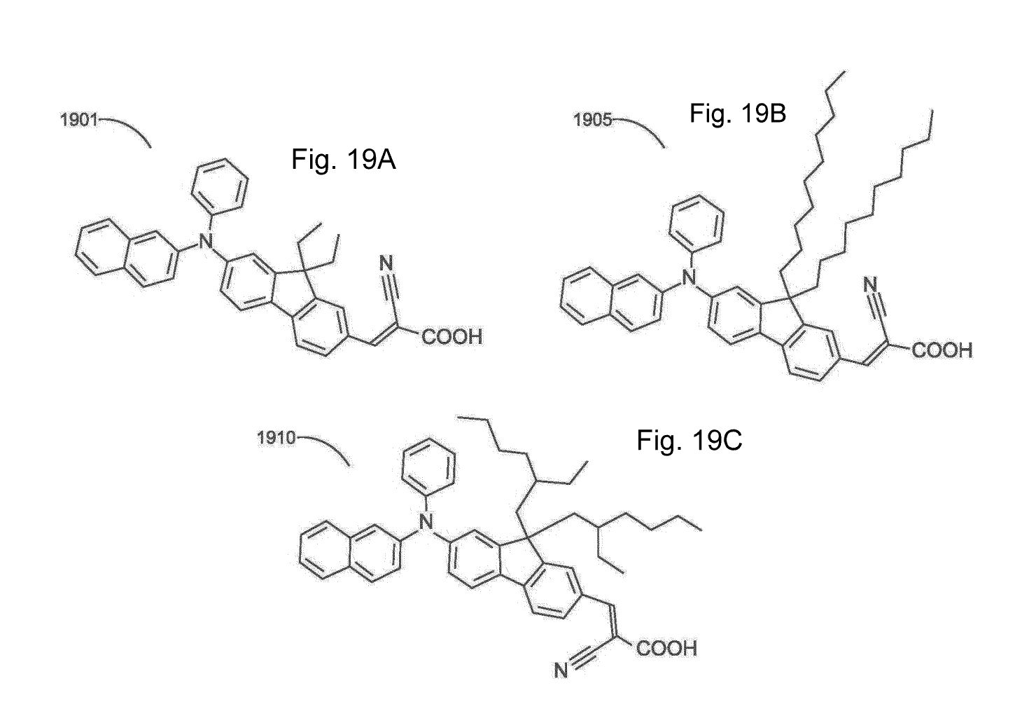

Returning to the example embodiments in which the core moiety comprises a fluorene, in embodiments employing C₂ alkyl tails, the core moiety could comprise a 9,9′-diethyl fluorene. Likewise, in embodiments wherein the alkyl tails each comprise a C₃ hydrocarbon, the core moiety of such embodiments may comprise a 9,9′-dipropyl fluorene, or in other embodiments (using another C₃ isomer), a 9,9′-dimethylethyl fluorene. Any other C₂ to C₁₀ isomer may be used. Or, in other embodiments, any other C₂ to C₁₅, C₂ to C₂₀, C₂ to C₃₀, or C₂ to C₄₀ isomer may be used. FIG. 19 depicts the use of various alkyl tails on the fluorescent moiety of various embodiments of photoactive compositions, such as ethyl (C₂), decyl (C₁₀), and ethylhexyl (C₈, branched) alkyl tails.

In some embodiments, an alkyl tail or tails may provide spacing between different molecules of this photoactive composition. This may, for example, increase the light-to-power conversion efficiencies (PCEs) of PV cells comprising the photoactive composition. The spacing provided by the alkyl tail or tails may vary depending upon the makeup of the photoactive composition of some embodiments (e.g., different alkyl tails may be ideal for compositions comprising different primary electron donating moieties). In addition, the alkyl tail or tails may provide enhanced solubility when the photoactive compositions of the present disclosure are employed in the presence of a solvent (such as, for example, where the photoactive compositions are used or intended to be used in a DSSC, BHJ, or hybrid OPV device). The alkyl tail or tails of some embodiments may therefore depend upon the identity of the solvent used. Possible solvents include, but are not limited to: dichlorobenzene, chlorobenzene, toluene, methylene chloride, chloroform, acetonitrile, N,N-dimethylformamide, isopropanol, t-butanol, ethanol, methanol, and water.

Thus, the present disclosure in some embodiments also provides for methods for selecting the ideal alkyl tail based at least upon the following considerations: makeup of the photoactive composition (and/or its constituent parts, such as the identity of the primary electron donor moiety), ability to be sublimed, and the characteristics of the solvent, if any, into which the photoactive composition is to be employed. These methods may in some embodiments be employed on their own, or in other embodiments employed in connection with the methods for selecting a primary electron donor moiety and an electron withdrawing moiety, discussed previously.

In some embodiments, the alkyl tail selection method comprises selecting an alkyl tail based in part upon the size of the primary electron-donating moiety of the photoactive composition. In some embodiments, this selection comprises selecting a longer alkyl tail (that is, an alkyl tail with a longer chain, whether or not that chain further comprises branches) to correspond to a larger primary electron donor moiety. The method of some embodiments may further or instead comprise selecting a longer alkyl tail to correspond to a less polar solvent, or selecting a shorter alkyl tail to correspond to a more polar solvent. The method of other embodiments may further or instead comprise selecting a longer alkyl tail when the photoactive composition comprises more aromatic (ring) hydrocarbons.

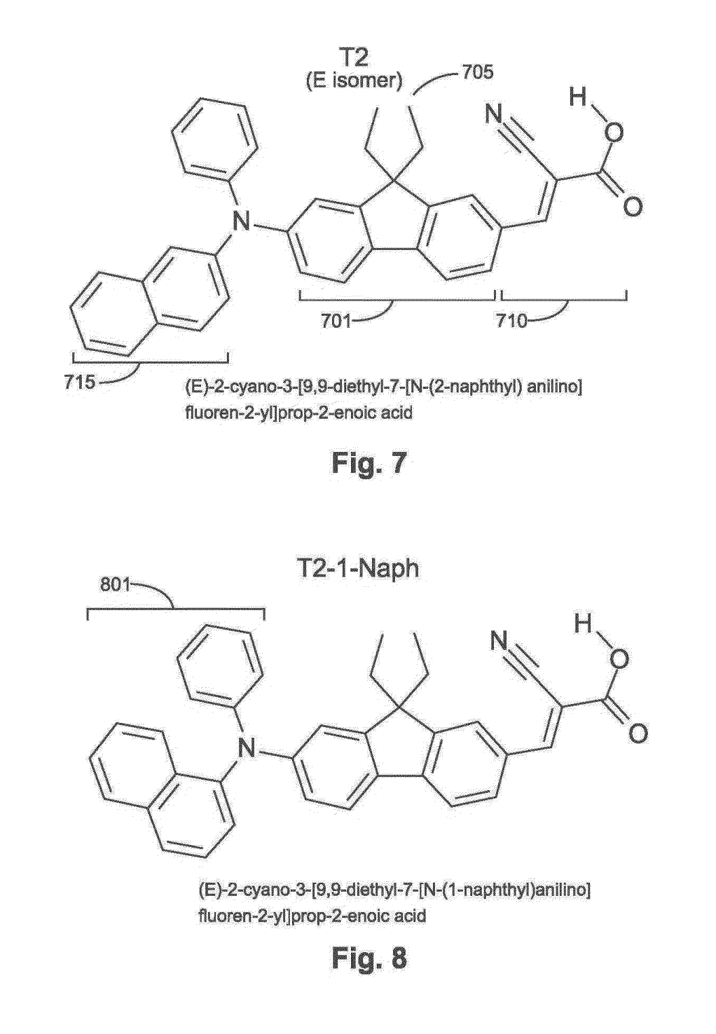

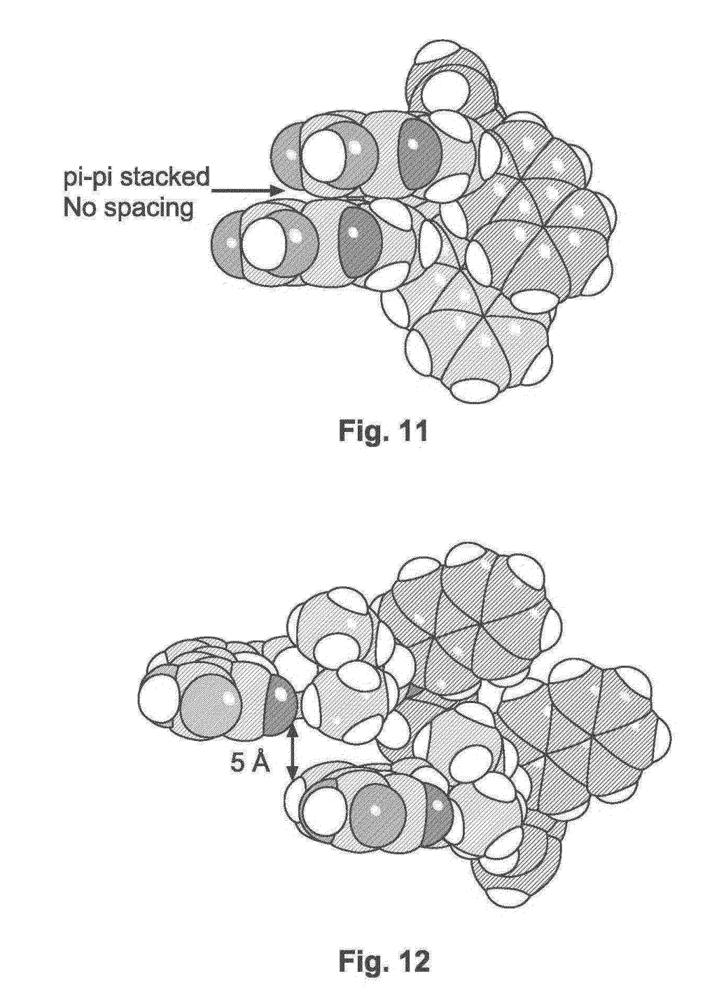

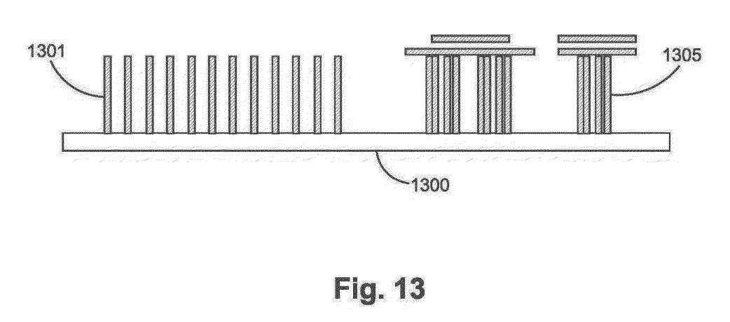

FIG. 11 illustrates examples of molecular stacking resulting from the presence of aromatic (ring) hydrocarbons in the photoactive composition. FIG. 11 is a molecular model of multiple molecules of a derivative of the composition T2 (of FIG. 7), but without the alkyl tails 705. FIG. 12 illustrates examples of employing alkyl tails to provide intermolecular spacing among molecules of the photoactive composition (FIG. 12 is a molecular model of multiple molecules of the composition T2 of FIG. 7 with diethyl alkyl tails 705 appended to the 9,9′ carbon of the fluorene 701 of T2). This intermolecular spacing may be necessary to prevent undesirable pi-pi stacking, the bonding interaction between two or more sets of pi-orbitals, which, may lead to detrimental clustering of multiple molecules of the photoactive composition, as depicted in FIG. 13. FIG. 13 shows a stylized example of employment of photoactive compositions as a dye on a DSSC. It depicts correctly aligned dye molecules 1301 on a surface 1300 (e.g., TiO₂), as well as 1305 clustered dye molecules on the surface 1300. The alkyl tails of some embodiments of the present disclosure prevent the undesirable clustering 1305, instead leading the dye molecules to maintain intermolecular spacing as with the correctly aligned dye molecules 1301. In other embodiments for applications such as BHJ, OPV, and FET, pi-pi stacking is desirable to induce molecular ordering. In such a case, alkyl tails are used to control the extent and direction of said pi-pi stacking. In some embodiments, the alkyl tail or tails provide advantageous intermolecular spacing when the composition is employed as a dye on a DSSC, BHJ, or hybrid OPV, as represented in FIG. 13 by the correctly aligned dye molecules 1301, as compared to the clustered dye molecules 1305.

In embodiments in which the photoactive composition comprises more than one alkyl tail, the alkyl tails may, in some embodiments, be identical. In other embodiments, they may be different. And in some embodiments, the alkyl tails may be appended to the same carbon atom of the photoactive composition, while in other embodiments, the alkyl tails may be appended to different carbon atoms of the photoactive composition.

Where the alkyl tails are different and bonded to the same carbon atom, however, chirality of the overall composition may result. Having isomers of different chirality intermixed may, in some cases, require alternating molecules of different chiralty to achieve optimum intermolecular spacing. Thus, in some embodiments, the photoactive composition may comprise two or more different alkyl tails appended to the same carbon such that it is chiral. Relatedly, some embodiments of the present disclosure may provide a method comprising isolating molecules of only one chirality (and a photoactive composition so isolated and thereby containing only molecules of one chirality). Other embodiments may comprise molecules of mixed chirality, and other embodiments may comprise a method of alternating the R- and S-isomers so as to achieve optimum intermolecular spacing. Further, yet other embodiments may comprise a method of alternating any one or more of the following: D isomers, L isomers, and diastereomers.

Primary Electron Donor Moiety

In some embodiments, the primary electron donor moiety comprises an electron-donating group such as an amine (e.g., an amino substituent). In some embodiments, the primary electron donor moiety comprises an aryl amine, such as a mono- or diaryl amine. In other words, suitable amino substituents may be of the general formula R₁R₂N—, where R₁ and R₂ may or may not be equivalent chemical structures. For example, in some embodiments, R₁ and R₂ are both phenyls (e.g., a diphenylamino substituent). In other embodiments, R₁ may be a phenyl group and R₂ a naphthyl group (e.g., a napthyl-phenylamino, or naphthylanilino, substituent). In yet other embodiments, R₁ and R₂ may both be a napthyl group (e.g., a dinaphthylamino substituent). Furthermore, although any number of isomers may be used in various embodiments, the amino group of some embodiments may comprise the 2-naphthyl anilino isomer (e.g., an N-(2-naphthyl)anilino substituent). In some embodiments, the primary electron donor moiety may comprise a diphenylamine substituent, and in other embodiments, the primary electron donor moiety may comprise a naphthyl triarylamine. Embodiments in which the primary electron donor moiety comprises either of these two classes of substituents may exhibit improved properties by increasing the level of intramolecular delocalization and due to pi-donation from these aromatic groups.

The primary electron donor moiety of other embodiments may comprise a monoaryl amino substituent, such as a methylphenylamino group (e.g., R₁ is a methyl group and R₂ is a phenyl group), or a methylnaphthylamino group (e.g., R₁ is a methyl group and R₂ is a naphthyl group). R₁ may, in other embodiments, by ethyl, propyl, or any other moiety. It will additionally be appreciated by one of ordinary skill in the art that any other aryl amino or amino functional group can be used as the amine in embodiments wherein the electron donor moiety comprises an amine.

In other embodiments, the nitrogen (N) of the above-discussed amino compounds may be substituted by another trivalent element from Group 15 of the Periodic Table of the Elements. For example, in some embodiments, the nitrogen (N) may be substituted by phosphorous (P), arsenic (As), or antimony (Sb). That is, the primary electron donor moiety may comprise a phosphine (e.g., R₁R₂P—), an arsine (e.g., R₁R₂As—), or a stibine (e.g., R₁R₂Sb—). The R₁ and R₂ of these compounds may be any of the compounds discussed previously with respect to R₁R₂N. Thus, for example, the primary electron donor moiety may comprise a monoaryl phosphine, or a diaryl phosphine (such as a napthyl-phenylphosphino) substituent.

In other embodiments the primary electron donor moiety may comprise a divalent substituent, such as an ether (of the general formula R—O—), a sulfide (of the general formula R—S—), or a selenide (of the general formula R—Se—). Again, the R of these formulae may be any of the R₁ or R₂ compounds discussed previously with respect to R₁R₂N.

In other embodiments, the primary electron donor moiety may comprise a substituent selected from any one or more of the following categories: alkyl, phenyl, phenol, alkoxy phenyl, dialkoxy phenyl, alkyl phenyl, phenol amine, alkoxy phenyl amine, dialkoxy phenyl amine, alkyl phenyl amine, multicyclic aromatic substituents (e.g., naphthylene, anthracene), and combinations thereof.

Furthermore, in some embodiments, the primary electron donor moiety, regardless of its makeup, is at the opposing end of the composition from the electron-withdrawing moiety.

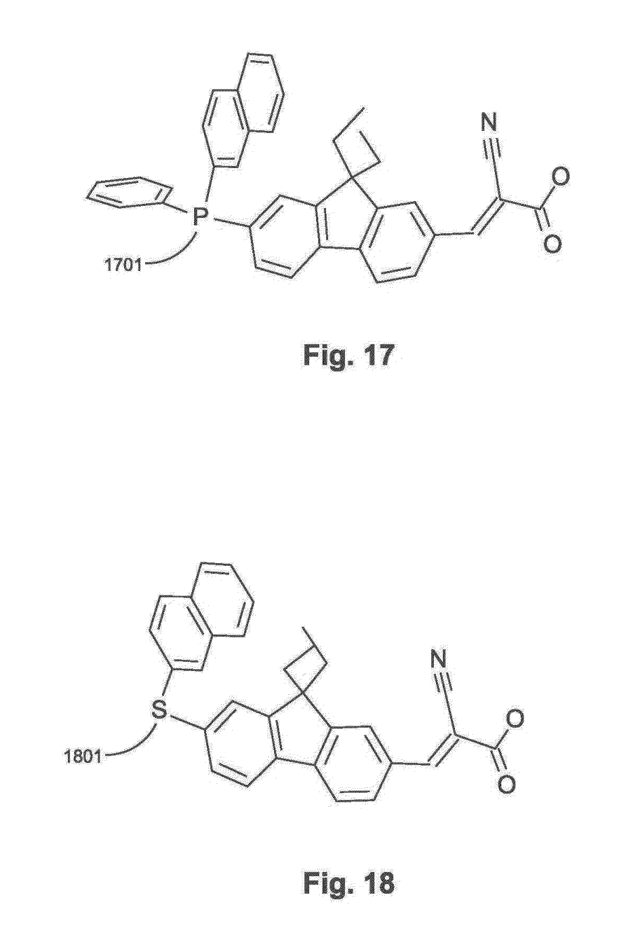

Selection of the primary electron donor moiety, with all other components of the composition being otherwise identical, may in some embodiments result in different properties. For example, Table 1 illustrates different HOMO, LUMO, E_{g}, and dipole moment values that result when the primary electron donor moiety comprises: an amine substituent; a phosphine substituent; an arsine substituent; an ether substituent; a sulfide substituent; or a selenide substituent. The amine, phosphine, and arsine substituents of Table 1 are of the structure shown in FIG. 17 (wherein N and As are used in place of the P 1701 of FIG. 17 for the amine and arsine, respectively); and the ether, sulfide, and selenide substituents of Table 1 are of the structure shown in FIG. 18 (wherein O and Se are used in place of the S 1801 of FIG. 18 for the ether and selenide, respectively).

TABLE 1

| Primary | | | LUMO | Dipole Moment |
|---|---|---|---|---|
| Electron Donor | Formula | HOMO (eV) | (eV) | (debye) |
| Amine | C₃₇H₃₀N₂O₂ | 5.08 | 2.44 | 5.26 |
| Phosphine | C₃₇H₃₀NO₂P | 5.71 | 2.56 | 2.98 |
| Arsine | C₃₇H₃₀AsNO₂ | 5.83 | 2.55 | 3.07 |
| Ether | C₃₁H₂₅NO₃ | 5.69 | 2.48 | 3.84 |
| Sulfide | C₃₁H₂₅NO₂S | 5.65 | 2.57 | 3.01 |
| Selenide | C₃₁H₂₅NO₂Se | 5.60 | 2.57 | 2.98 |

Thus, the present disclosure in some embodiments may further provide a method for selecting the primary electron donor moiety based upon one or more properties of the composition (e.g., HOMO, LUMO, and dipole moment) that would result, consistent with (or as part of) the design method discussed previously and exemplified in FIG. 6. In some embodiments, this may comprise selecting a class of electron donor moiety (e.g., amine, phosphine, arsine, ether, sulfide, selenide) based upon the general qualities exhibited by that class of electron donor moiety.

Electron-Withdrawing Moiety

In some embodiments, the electron-withdrawing moiety may be electron-poor. In some embodiments, it may be characterized by a higher electron affinity relative to the electron donor moiety and the core moiety. In other embodiments, the electron-withdrawing moiety may additionally be characterized by desirable electron orbital energy levels (e.g., HOMO/LUMO relative positions that provide advantageous organic semiconducting capabilities, such as a desired band gap E_{g}). Thus, in some embodiments, the electron-withdrawing moiety may comprise a carboxylic acid group in order to exhibit both characteristics (electron affinity and desired HOMO/LUMO relative positions). Examples of suitable carboxylic acid groups of some embodiments include cyanoacrylates. For example, FIG. 4 shows a photoactive composition consistent with the present disclosure in which the electron-withdrawing moiety comprises a cyanoacrylate (i.e., (Z)-2-cyano-3-[9,9′-diethyl-7-(N-phenylanilino)fluoren-3-yl]prop-2-enoic acid). In other embodiments, the electron-withdrawing moiety may comprise any one of the following: a monocyanocomplex, a dicyanocomplex, a thiocyanocomplex, or an isothiocyanocomplex. For example, FIG. 5 shows the photoactive composition 2-[[9,9-diethyl-7-(N-phenylanilino)fluoren-2-yl]methylene]propanedinitrile in which the electron-withdrawing moiety comprises a dicyanocomplex, but is otherwise identical to FIG. 4.

Furthermore, in some embodiments, the electron withdrawing moiety may further comprise a binding moiety; in other embodiments, the electron withdrawing moiety may additionally serve as a binding moiety, without the need to include a separate binding moiety. Thus, for example, in embodiments in which the electron withdrawing moiety comprises a carboxylic acid group, the carboxylic acid group may also function as the binding moiety. In some embodiments, the binding moiety may serve to bind the photoactive composition of matter to another substance such as a substrate (e.g., TiO₂), for example in DSSC applications. The binding moiety may also, in some embodiments, serve to bind the photoactive composition to other substances including, but not limited to, Au, Ag, FTO (fluorine-doped tin oxide), ITO (indium tin oxide), or Nb₂O₅, as a layer or into supramolecular extended structures, such as metal organic frameworks, covalent organic frameworks, or crystalline structures.

Illustrative Embodiments of Photoactive Compositions and their Tunability

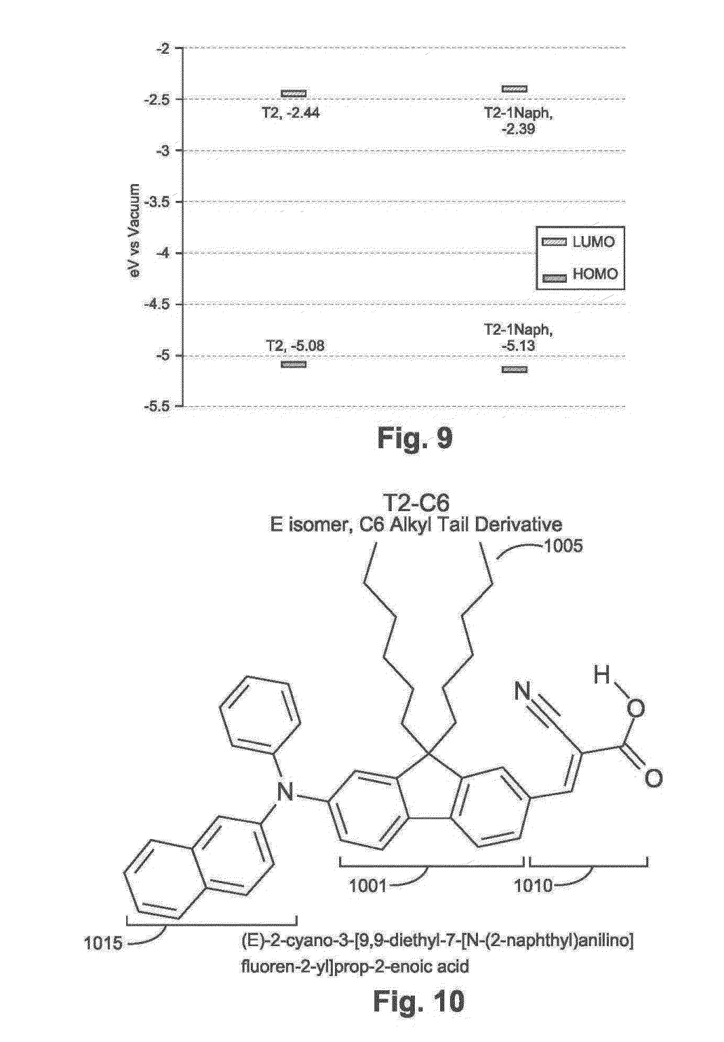

Consistent with the above, then, in one embodiment the photoactive compound may comprise 2-cyano-3-[9,9′-diethyl-7-[N-(2-naphthyl)anilino]fluoren-2-yl]prop-2-enoic acid in either the Z or E isomer (with reference to the C═C bond of the propenoic acid). FIG. 7 shows the E isomer, labeled T2, that is, (E)-2-cyano-3-[9,9′-diethyl-7-(N-phenylanilino)fluoren-2-yl]prop-2-enoic acid. In this embodiment, the core moiety 701 comprises fluorene, with two C₂ alkyl tails 705 appended to the 9,9′ carbon of the fluorene (that is, the core moiety comprises a 9,9′ diethyl fluorene). The electron-withdrawing moiety 710 comprises 2-cyanoprop-2-enoic acid, and is bonded at the 3 carbon of the propenoic acid to the core moiety. The primary electron donor moiety 715 here comprises an N-naphthylanilino substituent bonded to the 7 carbon of the fluorene. This embodiment specifically comprises the N-(2-naphthyl)anilino isomer, which exhibits the unexpected benefit of greater photoelectric power conversion efficiency (PCE) (when the compound is used in OPV applications such as a DSSC dye) over a compound that comprises instead the N-(1-naphthyl)anilino isomer 801, but is otherwise identical, as illustrated in FIG. 8 (labeled T2-1-Naph). Specifically, compounds comprising the N-(2-naphthyl)anilino isomer exhibit approximately 6.6% PCE, whereas otherwise identical compounds that instead employ the N-(1-naphthyl)anilino isomer exhibit approximately 6.0% PCE. One possible explanation for this enhanced efficiency is the significant electronic change in the composition that results when the primary electron donor moiety comprises the N-(2-naphthyl)anilino isomer. As shown in FIG. 9, the 2-naphthyl isomer T2 provides the composition with a superior (smaller) band gap (E_{g}) due to the resulting deeper LUMO (−2.44 eV vs vacuum) and shallower HOMO (−5.08 eV vs vacuum). Specifically, the 1-naphthyl E_{g} is 2.74 eV (again, this is the difference between the LUMO and HOMO), while the 2-naphthyl E_{g} is 2.64 eV, as shown in FIG. 9, which contains data derived from computations in molecular modeling software. In addition, the 2-naphthyl isomer additionally improves the absorptive properties of the composition, such as by red-shifting (e.g., permitting absorption of longer wave-length light, increasing the spectral window).

This comparison further illustrates some of the desirable electronic properties previously discussed with respect to tunability considerations, consistent with the design methods of various embodiments of the present disclosure. That is, selection of the 2-naphthyl isomer instead of the 1-naphthyl isomer results in smaller E_{g}, shallower HOMO, deeper LUMO, and therefore smaller E_{g}. This in turn has a positive effect on the PCE and on the absorptive properties of the composition.

Consistent with the above disclosure, other embodiments of compositions of the present disclosure may comprise alkyl tails of differing lengths. For example, embodiments comprising the same electron-donating and electron-withdrawing moieties, but different alkyl tails, include, but are not limited to: 2-cyano-3-[9,9-dipropyl-7-[N-(2-naphthyl)anilino]fluoren-2-yl]prop-2-enoic acid; 2-cyano-3-[9,9-dibutyl-7-[N-(2-naphthyl)anilino]fluoren-2-yl]prop-2-enoic acid; and so on up to and including C₁₀, C₁₅, C₂₀, C₃₀, or C₄₀ alkyl tails, consistent with the previous discussion of alkyl tails. The example embodiment (E) 2-cyano-3-[9,9-dihexyl-7-[N-(2-naphthyl)anilino]fluoren-2-yl]prop-2-enoic acid, for example, is labeled T2-C6 in FIG. 10, wherein the core moiety 1001, electron-withdrawing moiety 1010, and primary electron donor moiety 1015 comprise the same substituents as the embodiment T2 depicted in FIG. 7. But, as shown in FIG. 10, the alkyl tails 1005 appended to the 9,9′ carbon of the fluorene comprise a dihexyl substituent rather than the diethyl of T2 in FIG. 7. Similarly, FIG. 19 shows the substitution of C₂, C₁₀, and branched C₈ (ethylhexyl) alkyl tails on the 9,9′ carbon of fluorene in various embodiments 1901, 1905, and 1910, respectively.

Embodiments using branched alkyl tails (and, again, utilizing the same core, electron-donating, and electron-withdrawing moieties) include, but are not limited to: 2-cyano-3-[9,9-dimethylethyl-7-[N-(2-naphthyl)anilino]fluoren-2-yl]prop-2-enoic acid; 2-cyano-3-[9,9-dimethylpropyl-7-[N-(2-naphthyl)anilino]fluoren-2-yl]prop-2-enoic acid; and so on using any branched alkyl tail.

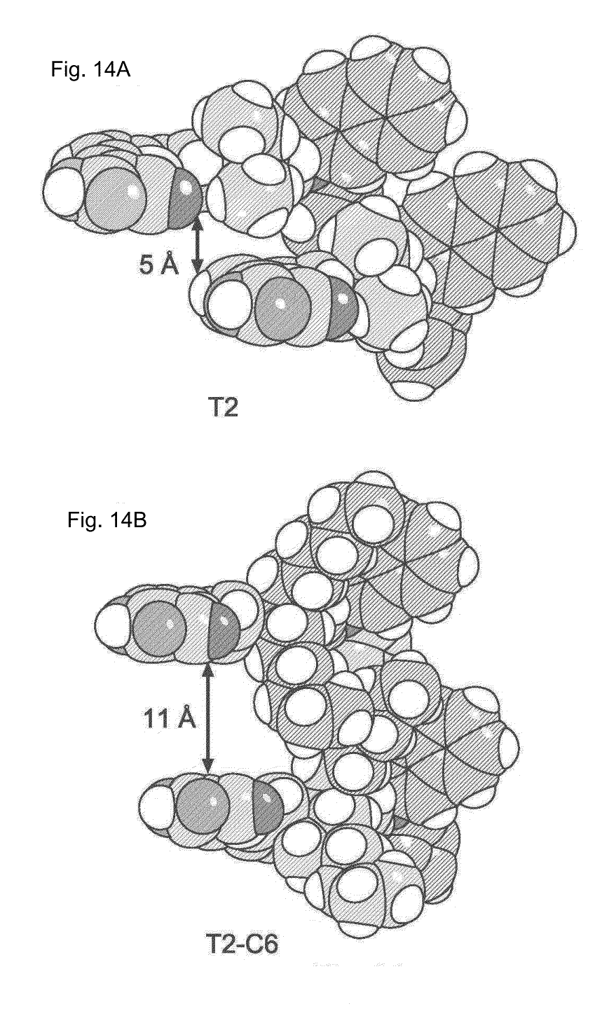

As discussed previously, alkyl tails of differing lengths may provide different properties, such as greater intermolecular spacing. Continuing with the example embodiment wherein the composition comprises 2-cyano-3-[9,9-diethyl-7-[N-(2-naphthyl)anilino]fluoren-2-yl]prop-2-enoic acid (that is, T2 of FIG. 7), FIG. 14 illustrates the molecular spacing difference achieved when substituting 9,9′ dihexyl alkyl tails 1005 in T2-C6 for the 9,9′ diethyl alkyl tails 705 of T2 (11 Å versus 5 Å). This additional spacing could, in some embodiments, prevent aggregation of the molecules of the compound, and thus result in higher device performance when the compound is used in an OPV. This composition difference again further illustrates the additional tunability consideration of intermolecular spacing, which may be taken into account in the design methods of various embodiments previously discussed, particularly at the alkyl tail selection step.

As also discussed previously, in some embodiments alkyl tail selection may depend upon other factors in order to determine the optimum alkyl tail. Table 2 below illustrates V_{OC} (open-circuit voltage), J_{SC} (Photocurrent density), Fill Factor (FF), and power conversion efficiency (PCE) for variations of the embodiment of FIG. 7 (that is, T2), employing different alkyl tails appended to the 9,9′ carbon of the fluorene.

TABLE 2

| Alkyl Tail | V_{OC} (mV) | J_{SC} (mA/cm²) | FF (%) | PCE (%) |
|---|---|---|---|---|
| 2C₂ (diethyl) | 780 | 10.7 | 68.5 | 5.70 |
| 2C₃ (dipropyl) | 780 | 12.0 | 65.2 | 6.10 |
| 2C₄ (dibutyl) | 780 | 10.4 | 66.3 | 5.10 |
| 2C₅ (dipentyl) | 753 | 11.3 | 60.0 | 5.10 |
| 2C₆ (dihexyl) | 728 | 10.4 | 66.0 | 5.00 |
| 2C₈ (dioctyl) | 774 | 10.4 | 62.0 | 5.00 |
| 2C₁₀ (didecyl) | 780 | 11.8 | 56.0 | 5.16 |

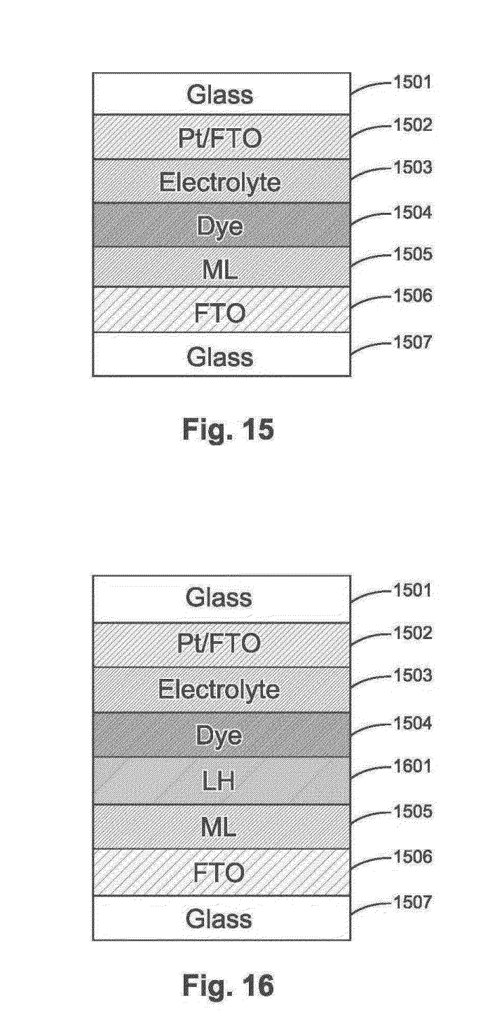

In Table 2, the composition is used as a dye on an OPV, as illustrated in FIG. 15. FIG. 15 depicts various layers in a typical DSSC: substrate layer 1501 (glass in FIG. 15); electrode layer 1502 (shown as Pt/FTO (F-doped tin oxide)); electrolyte 1503; dye 1504; ML (mesoporous layer, which in some embodiments may be TiO₂) 1505; electrode layer 1506 (shown as FTO); and substrate layer 1507 (shown as glass in FIG. 15). In the instances illustrated in Table 2, the composition is employed as a dye 1504 in the absence of a light harvesting layer. A light-harvesting layer may, in some embodiments, be employed to scatter incident light in order to increase its path length through the photoactive layer and therefore the light's probability of being absorbed.

Table 2 further demonstrates the relationship among PCE, V_{OC}, J_{SC}, and FF, which can be defined according to the following equation:

$$PCE = \frac{{V}_{OC} \times {J}_{SC} \times FF}{{P}_{0}}$$

where V_{OC}, J_{SC}, and FF are defined as above with respect to Table 2, and P₀ is incident light power density in W/m².

In contrast, Table 3 presents the same data for the same composition T2 (using varying alkyl tails appended to the 9,9′ carbon of the fluorene of T2 as indicated in Table 3) when the composition is employed as a dye 1504 with a Light Harvesting Layer 1601 added between the dye 1504 layer and the ML 1505, as represented in FIG. 16.

TABLE 3

| Alkyl Tail | V_{OC} (mV) | J_{SC} (mA/cm²) | FF (%) | PCE (%) |
|---|---|---|---|---|
| 2C₂ (diethyl) | 730 | 14.6 | 62.0 | 6.60 |
| 2C₃ (dipropyl) | 713 | 14.2 | 61.1 | 6.20 |
| 2C₄ (dibutyl) | 720 | 13.0 | 60.0 | 5.60 |
| 2C₅ (dipentyl) | 758 | 12.5 | 61.0 | 5.80 |
| 2C₆ (dihexyl) | 700 | 12.0 | 66.0 | 5.53 |
| 2C₈ (dioctyl) | 780 | 11.8 | 63.0 | 5.80 |
| 2C₁₀ (didecyl) | 780 | 12.3 | 61.0 | 5.86 |

As can be seen, while C₃ alkyl tails provide the greatest PCE in the absence of a light harvesting layer, C₂ alkyl tails provide the greatest PCE in the presence of a light harvesting layer. Thus, in some embodiments, the method of alkyl tail selection comprises selecting an alkyl tail based in part upon the presence of a light harvesting layer, which is shown by Tables 2 and 3 to be an additional tunability consideration consistent with the methods of various embodiments previously discussed. In other embodiments, the method of alkyl tail selection comprises selecting an alkyl tail based in part upon any one or more device architectural feature(s), which are also tunability considerations.

It will further be appreciated by one of ordinary skill in the art that other embodiments may comprise different primary electron-donating moieties and/or electron-withdrawing moieties consistent with the previous discussion regarding each of those moieties. For example, FIG. 4 shows another embodiment of a photoactive compound of the present disclosure: (Z)-2-cyano-3-[9,9′-diethyl-7-(N-phenylanilino)fluoren-2-yl]prop-2-enoic acid. In this instance, the core moiety 415, alkyl tails 410, and electron-withdrawing moiety 405 are the same as in T2 of FIG. 7, but the primary electron donor moiety 401 of the embodiment depicted in FIG. 4 comprises an N-phenylanilino substituent instead of the N-(2-naphthyl)anilino substituent of the primary electron donor moiety 715 of T2 in FIG. 7. And FIG. 5 shows an embodiment differing from the embodiment of FIG. 4 only in that the embodiment of FIG. 5 comprises a different electron-withdrawing moiety 505: 2-(methylene)propanedinitrile instead of 2-cyano-prop-2-enoic acid (as in FIG. 4). And in some embodiments, the different primary electron donor moieties and/or electron-withdrawing moieties may be selected based upon the methods of design previously discussed.

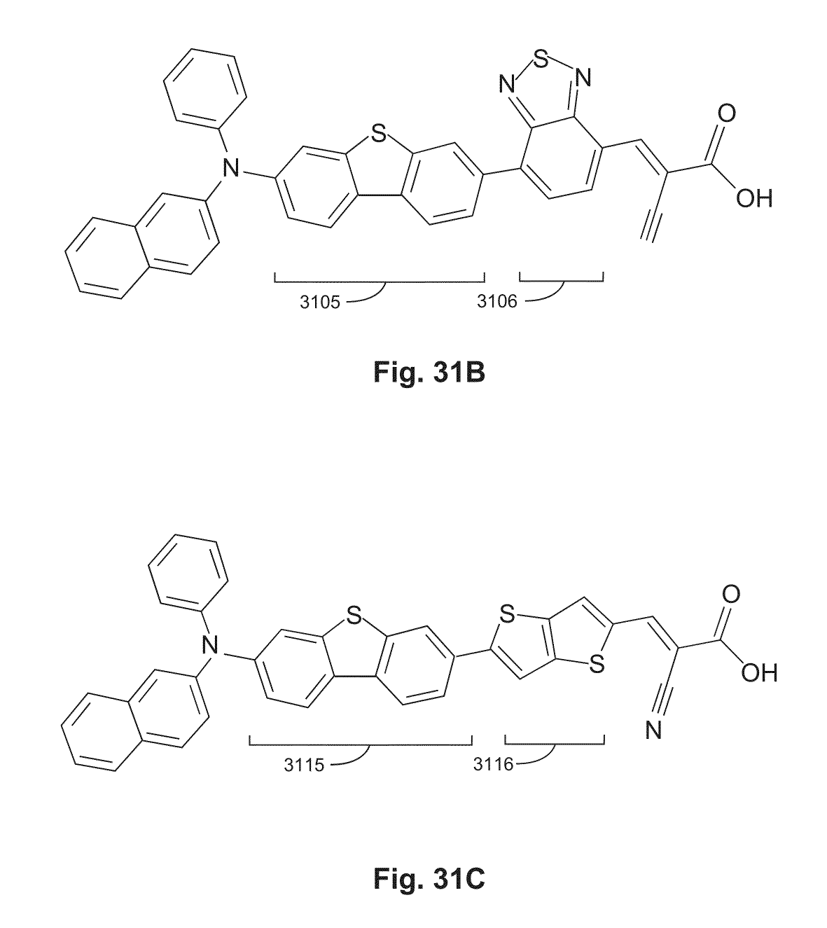

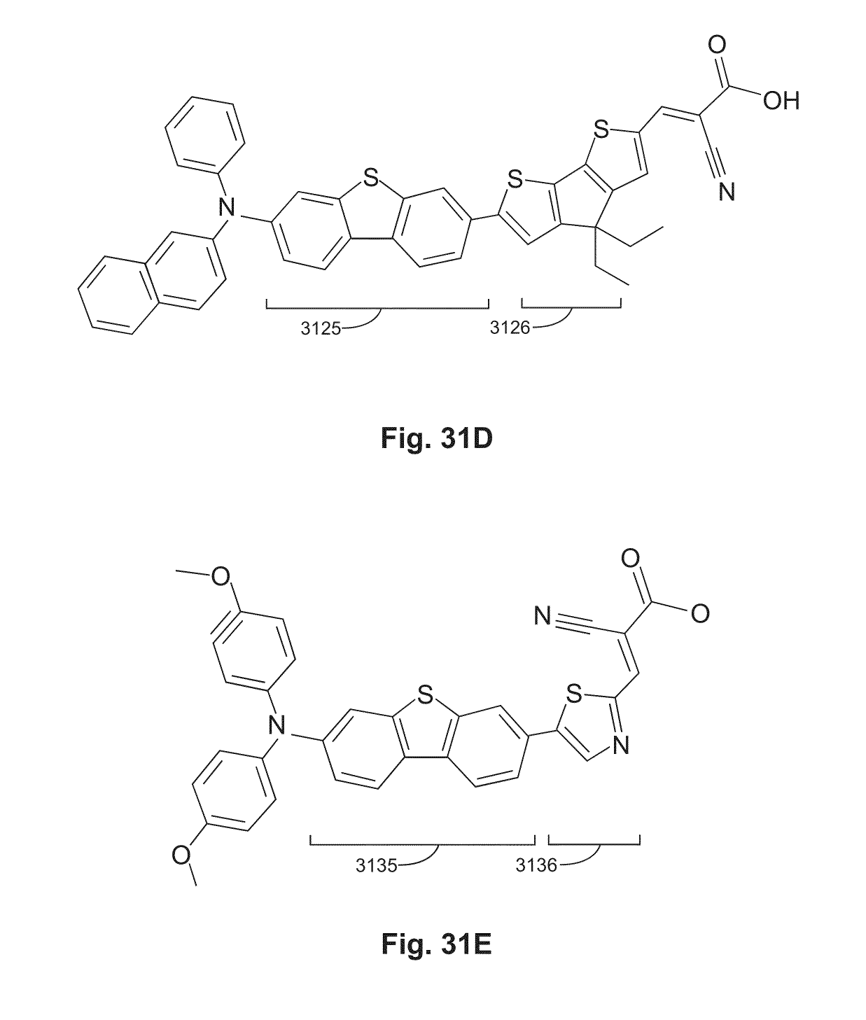

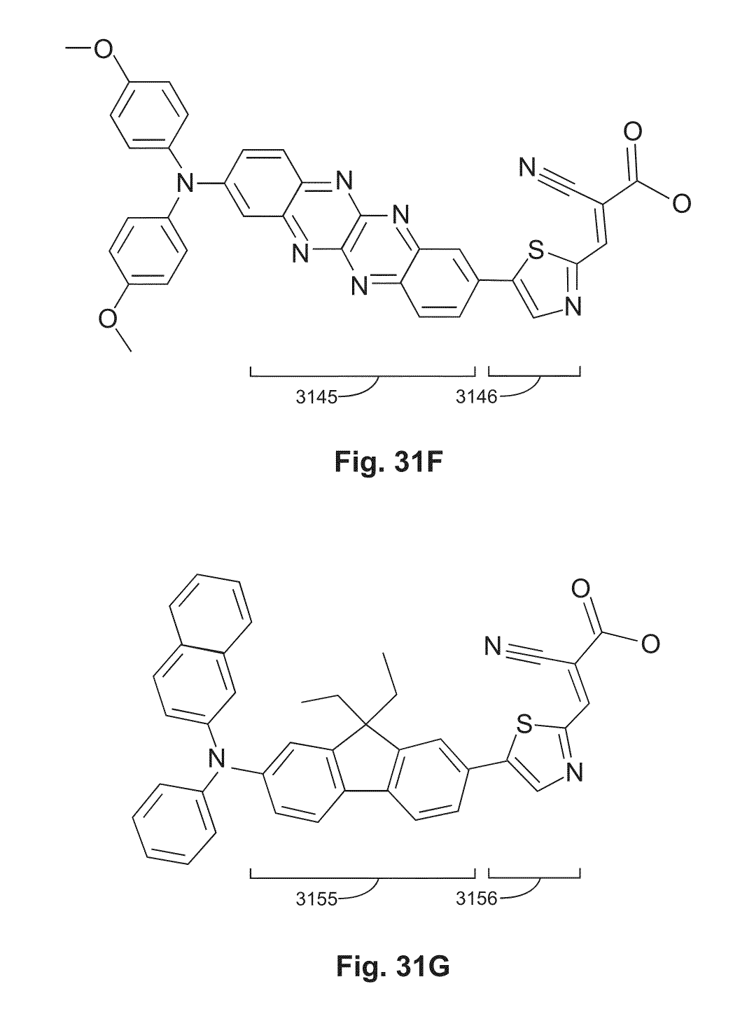

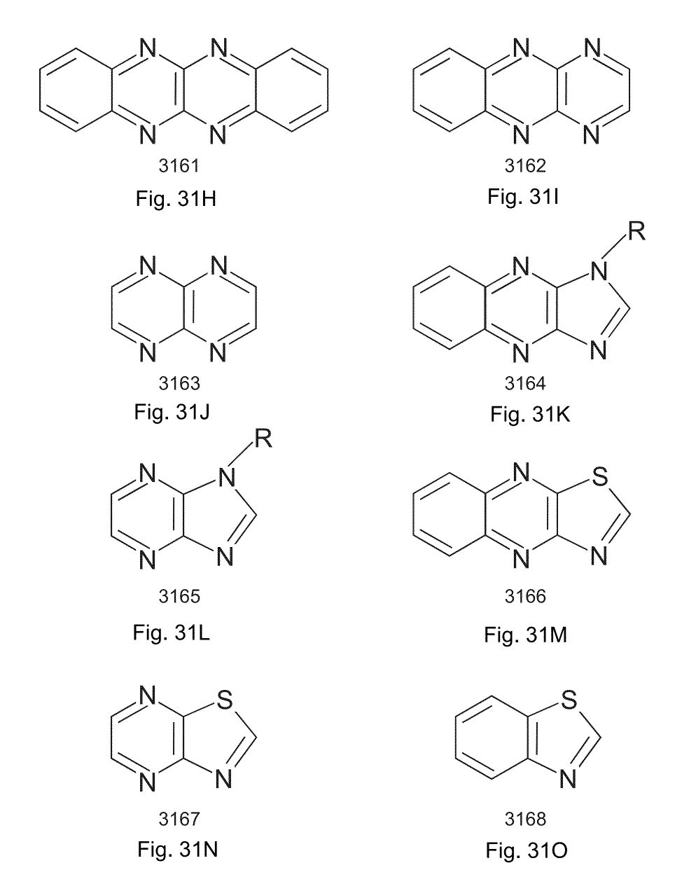

Likewise, some embodiments may comprise different core moieties. For example, FIGS. 31B-31E depict embodiments wherein the core moiety comprises a dibenzothiophene (3105, 3115, 3125, and 3135, respectively). Such embodiments further include second electron donor moieties (e.g., 3106, 3116, 3126, and 3136 respectively), discussed in greater detail below. Specifically, FIG. 31B depicts (E)-2-cyano-3-(7-(7-(naphthalen-2-yl(phenyl)amino)dibenzo[b,d]thiophen-3-yl)benzo[c][1,2,5]thiadiazol-4-yl)acrylic acid. FIG. 31C depicts (E)-2-cyano-3-[5-[7-(naphthalen-2-yl(phenyl)amino)dibenzo[b,d]thiophen-3-yl]thieno93,2-b]thiophen-2-yl]acrylic acid. FIG. 31D depicts (E)-2-cyano-3-[4,4-diethyl-6[7-(naphthalen-2-yl(phenyl)amino)dibenzo[b,d]thiophen-3-yl]-4H-cyclopenta[1,2-b:5,4-b′]dithiophen-2-yl]acrylic acid. FIG. 31E depicts (E)-2-cyano-3-[5-[7-(4-methoxy-N-(4-methoxyphenyl)anilino)dibenzothiophen-3-yl]thiazol-2-yl]prop-2-enoic acid.

By way of further example, FIG. 31F depicts (E)-2-cyano-3-[5-[2-(4-methoxy-N-(4-methoxyphenyl)anilino)quinoxalino[3,2-b]quinoxalin-8-yl]thiazol-2-yl]prop-2-enoic acid. Here, the core moiety comprises a quinoxalino-quinoxaline (3145), and the compound also includes a second electron donor moiety 3146.

Yet further examples of suitable core moieties are shown in FIG. 31H. FIG. 31H depicts various nitrogen heterocycle compounds which may be useful as either or both of core moieties or electron donor moieties (either primary or second and/or additional electron donor moieties, discussed in more detail below). The exemplary nitrogen heterocycles of FIG. 31H include: pyrazino[2,3-b]pyrazine 3161; imidazo[4,5-b]quinoxaline 3162; pyrazino[2,3-b]pyrazine 3163; imidazo[4,5-b]quinoxaline 3164; imidazo[4,5-b]pyrazine 3165; thiazolo[4,5-b]quinoxaline 3166; thiazolo[4,5-b]pyrazine 3167; and 1,3-benzothiazole 3168.

Second and Additional Electron Donor Moieties

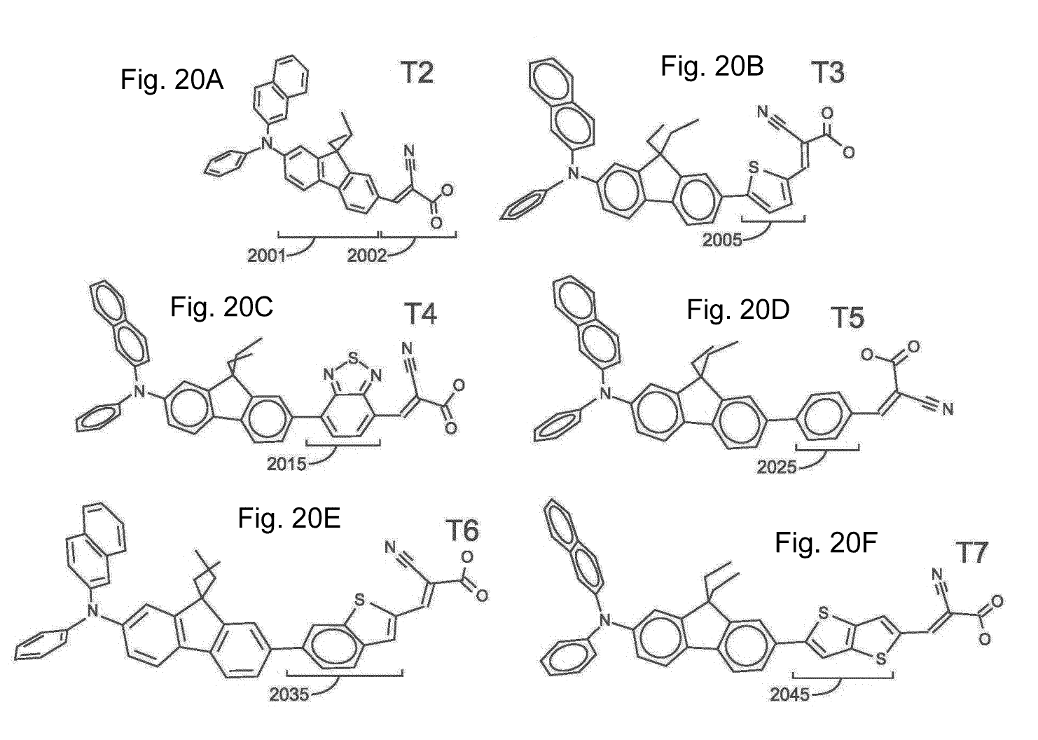

Referring back to FIG. 2, the photoactive compositions of some embodiments may further comprise a second electron donor moiety 5, which in some embodiments is disposed between the core moiety 1 and the electron-withdrawing moiety 3. The second electron donor moiety may, in some embodiments, serve to further tune the absorption window (i.e., the allowed absorption wavelengths based on the band gap) of the photosensitive compositions of such embodiments. For example, in some embodiments, the second electron donor moiety may result in beneficial reduction of the band gap E_{g} between the HOMO and LUMO of the photoactive composition. The second electron donor moiety may, in some embodiments, comprise a pi-electron donor. Any pi-electron donor moiety is suitable. As previously noted, FIGS. 31B-31F depict various example compositions comprising second electron donor moieties 3106, 3116, 3126, 3136, and 3146. FIG. 20 likewise depicts various other embodiments of compositions of the present disclosure, many of which include a second electron donor moiety. Specifically: T3 comprises a second electron donor moiety 2005 comprising thiophene; T4 comprises a second electron donor moiety 2015 comprising benzothiadiazole; T5 comprises a second electron donor moiety 2025 comprising a phenyl moiety; T6 comprises a second electron donor moiety 2035 comprising benzothiophene; and T7 comprises a second electron donor moiety 2045 comprising thienothiophene. Additionally, FIG. 31G depicts yet another embodiment comprising a second electron donor moiety 3156. And, as also previously noted, FIG. 31H depicts several nitrogen heterocycles that may be suitable second electron donor moieties. For comparison, T2 of FIG. 20 shows a photosensitive composition with no second electron donor moiety, with the core moiety 2001 (a 9,9′-diethyl fluorene) bonded directly to the electron-withdrawing moiety 2002 (2-cyano prop-2-enoic acid) on the 3-carbon of the acid. T2 of FIG. 20 is also the embodiment T2 illustrated in FIG. 7, that is, (E)-2-cyano-3-[9,9-diethyl-7-[N-(2-naphthyl)anilino]fluoren-2-yl]prop-2-enoic acid. Other examples of suitable second electron donor moieties include, but are not limited to: benzothiazole, benzothiophene, dibenzothiophene, naphthothiophene, dinaphthothiophene, benzonaphthothiophene, 4H-cyclopenta[1,2-b:5,4-b′]bisthiophene, thieno[3,2-b]thiophene, benzo[b][1]benzosilole, thiazole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, and combinations thereof.

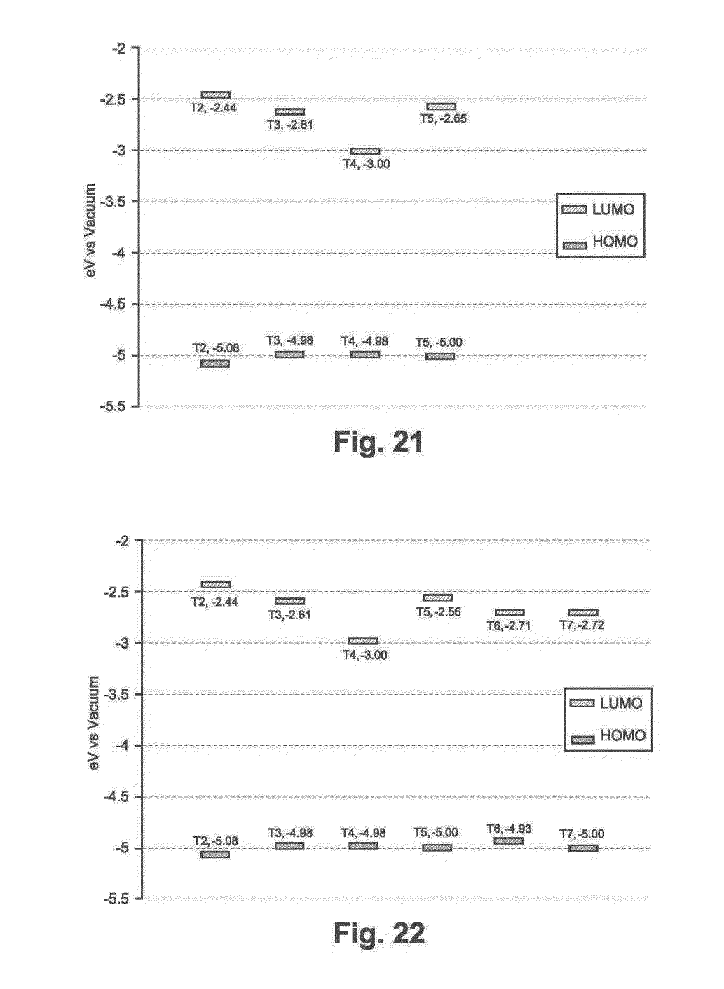

Referring back to FIG. 20, the compositions T3, T4, T5, T6, and T7 (comprising the second electron donor moieties discussed previously) may exhibit smaller E_{g} values than exhibited in T2 (also shown in FIG. 7), that is, (E)-2-cyano-3-[9,9-diethyl-7-[N-(2-naphthyl)anilino]fluoren-2-yl]prop-2-enoic acid. As shown in FIG. 21, the E_{g} of T3 is 2.37 eV; the E_{g} of T4 is 1.98 eV; and the E_{g} of T5 is 2.44 eV, while the E_{g} of T2 is 2.64 eV. And as shown in FIG. 22, the E_{g} of T6 is 2.22 eV, and the E_{g} of T7 is 2.28 eV. The data shown in FIGS. 21 and 22 were derived from computations in molecular modeling software.

Accordingly, in some embodiments, the present disclosure further provides for a method of selecting a second electron donor moiety based upon the resulting effect on the HOMO and LUMO (and therefore band gap E_{g}) of the composition, consistent with (or in conjunction with) the design methods of various embodiments previously discussed. That is, in some embodiments, the second electron donor moiety selection step 607 may comprise selection of a second electron donor moiety based at least in part upon the resulting effect on the HOMO and LUMO (and therefore band gap E_{g}) of the composition, as demonstrated for example in FIGS. 21 and 22.

The compounds of some embodiments may comprise more than two electron donor moieties. Third (and greater) electron donor moieties may be selected for addition to the compound according to any of the tunability characteristics discussed herein. For example, a third (or greater) electron donor moiety may be selected for addition to the compound in order further to reduce E_{g}, and/or to modify either or both of the HOMO and LUMO energy levels. Any moiety suitable as a primary or second electron donor moiety may be used as a third or greater electron donor moiety in these embodiments.

Second and Additional Electron-Withdrawing Moieties

The compounds of some embodiments may comprise a second electron-withdrawing moiety. In some embodiments, the second electron-withdrawing moiety may be any moiety suitable for inclusion as an electron-withdrawing moiety, as discussed previously. In other embodiments, the second electron-withdrawing moiety may comprise a substituent that is electron-poor, but is not suitable for binding the compound to a substrate or other surface. That is, in these embodiments it may be preferable to select the second electron-withdrawing moiety from a different subset of moieties than the subset from which the first electron-withdrawing moiety is selected. Thus, in some embodiments, second electron-withdrawing moieties may comprise any one or more of the following: perfluorophenyls, acridones, triazines, and perylene imides. Some embodiments may also comprise three or more electron-withdrawing moieties; these moieties may be selected from any moiety suitable for use as a second electron-withdrawing moiety.

Synthesis

In other embodiments, the present disclosure provides for methods of synthesizing photosensitive compositions.

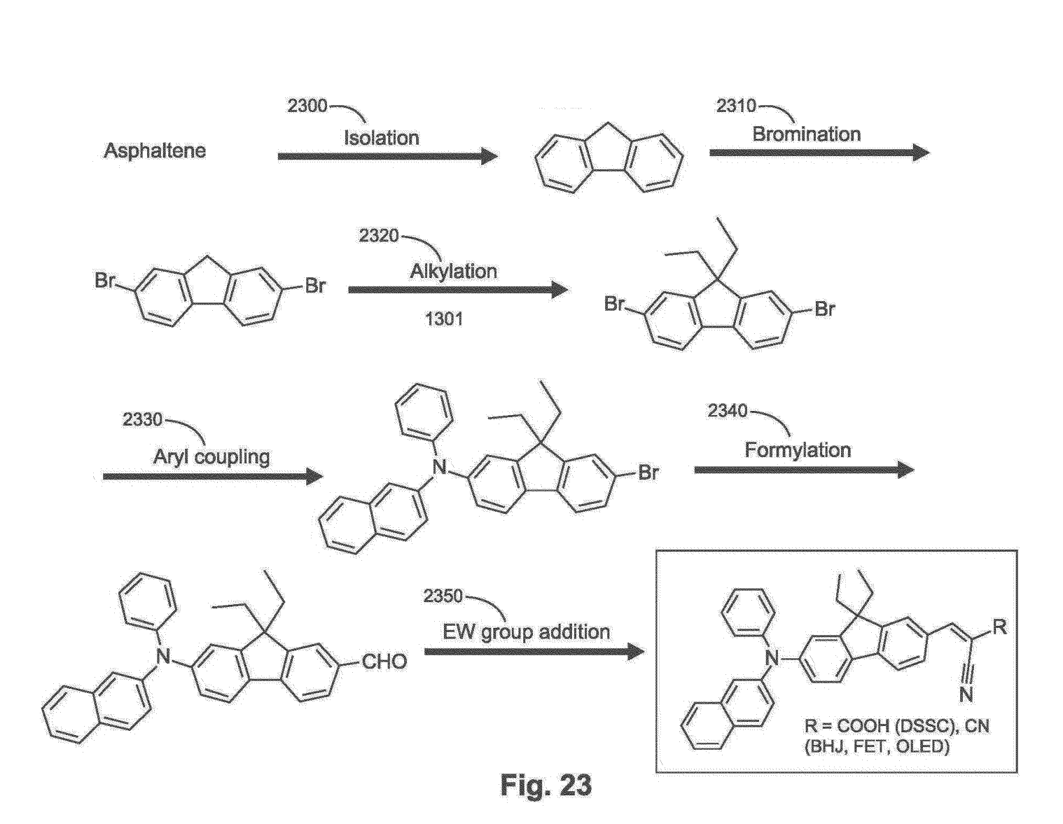

The process of one example embodiment is described as follows, and with reference to FIG. 23. Each step referred to herein may be accomplished by any of various reaction mechanisms known in the art. Initially, fluorene is obtained by boiling asphaltene samples in ethanol to yield a pale yellow solution. The solution is cooled and then filtered followed by concentration in boiling ethanol. The hot solution is allowed to slowly cool in sand or vermiculite to yield colorless crystals. The obtained fluorene can be further purified, for example, by column chromatography. The foregoing procedure is outlined in FIG. 23 as “Isolation” 2300. The fluorene is first converted into the 4,4′-dibromo derivative, labeled “Bromination” 2310. Next, appropriate alkyl tails are added at the 9,9′ position of fluorene by formation of the fluorene anion followed by addition of the selected alkylbromide, which include ≧C₁ linear chains such as ethyl, n-propyl or n-decyl, or branched chains like ethylhexyl, in “Alkylation” 2320. Following is the formation of the fluorene-arylamine in the 4-position of the fluorene by a Buchwald-Hartwig coupling with such primary electron donor moieties as diphenylamine, naphthyl-phenylamine, or methylphenylamine, in “Aryl Coupling” 2330. The aldehyde is next formed in the 4′ position of the fluorene by lithiation in N-formylpiperidine followed by acid quenching, as depicted by “Formulation” 2340. In addition, an electron withdrawing moiety is added. Following the example set forth in FIG. 23, in “EW group addition” 2350, the cyanoacrylate complex is synthesized by reacting the previously formed aldehyde with cyanoacetic acid in refluxing acetic acid with ammonium acetate promoter.

In some embodiments, “EW group addition” 2350 will determine or depend upon the intended or actual application of the photoactive compound. Thus, in some embodiments, synthesis of a dicyanocomplex instead of the cyanoacrylate complex previously referenced would be suitable for small molecule devices (e.g., OPVs, FETs, OLEDs), when R is CN in FIG. 23. The cyanoacrylate complex formed in other embodiments, on the other hand, would be useful in DSSCs.

Compounds Used in Photovoltaic Cells and Other Electronic Devices

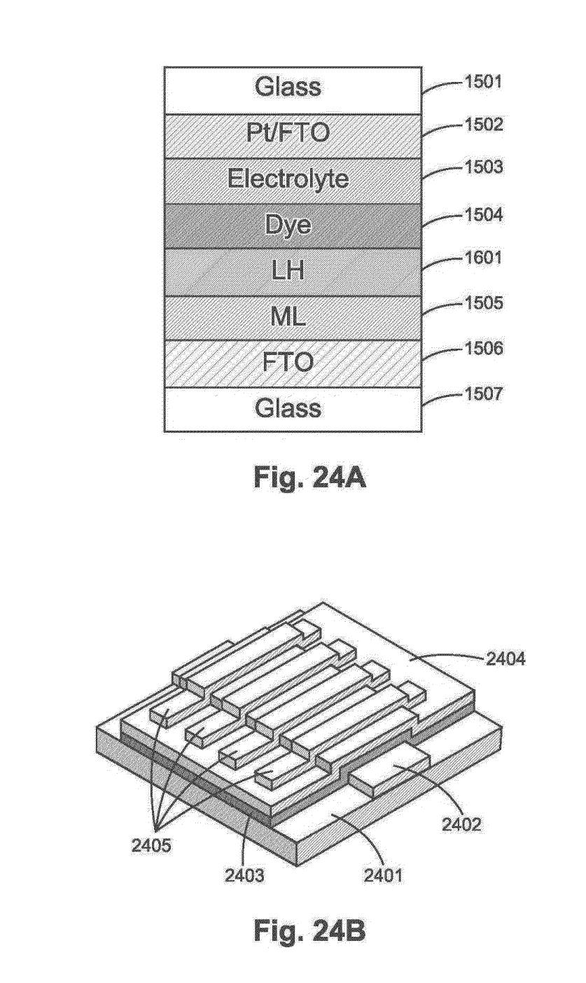

In other embodiments, the present disclosure provides for methods of determining applications for the photosensitive compounds, and for employing the compounds in a selected application. Thus, in some embodiments, the present disclosure provides a method of application of photosensitive compounds to PVs. In some embodiments, once design and synthesis of a photosensitive compound is completed, it may be tested to determine the appropriate device structure for its application, as set forth previously and as shown in FIG. 6. Appropriate device structures may be, e.g., DSSC or BHJ, as shown in FIGS. 24A and 24B. FIG. 24A is an illustration of a typical DSSC (shown with a light-harvesting layer), as depicted in FIG. 16. FIG. 24B is an illustration of typical BHJ device design, and includes: glass substrate 2401; ITO (tin-doped indium oxide) electrode 2402; interfacial layer (IFL) 2403; photoactive layer 2404; and LiF/Al cathodes 2405. The materials of BHJ construction referred to are mere examples; any other BHJ construction known in the art may be used consistent with the present disclosure. In some embodiments, the compositions of the present disclosure may be employed in the photoactive layer 2404 of the BHJ, or in the dye layer 1504 of a DSSC.

Typical performance parameters of some embodiments can be seen in Table 4 with PCE≈6.5% when T2 is employed as the DSSC dye 1504, and PCE≈1.4% when it is instead employed as the electron donor in the photoactive layer 2404 of the BHJ. In some embodiments, such test data may at least partially form the basis for determining the application in which a photoactive composition will be employed. Taking the example of T2, in such embodiments it may be determined that T2 should be employed as a DSSC rather than a BHJ. In other embodiments, this test data may suggest further modification of T2 according to the design methods of the present disclosure, keeping in mind the relevant tunability considerations shown in Table 4 and discussed throughout this disclosure.

TABLE 4

| Device | V_{OC} (mV) | J_{SC} (mA/cm²) | FF (%) | PCE (%) |
|---|---|---|---|---|
| BHJ | 780 | 3.77 | 44.0 | 1.37 |
| DSSC | 734 | 10.7 | 65.5 | 6.48 |

The present disclosure in some embodiments likewise provides PVs comprising a photoactive compound of the present disclosure. In some embodiments, the PV may be an OPV. In some embodiments, the OPV may be a DSSC, wherein the dye comprises a photoactive compound of the present disclosure. In some embodiments, the OPV may be a BHJ, wherein the photoactive layer of the BHJ comprises a photoactive compound of the present disclosure. Any DSSC, BHJ, or OPV generally as known in the art may advantageously incorporate a compound of the present disclosure, which may provide substantial benefits over conventional OPVs, particularly greater PCE to cost ratios.

Some embodiments of the present disclosure may be described by reference to the dye-sensitized solar cell depicted as stylized in FIG. 15, wherein the dye 1504 comprises a photoactive compound of the present disclosure. The cell may otherwise be comprised of any DSSC structure known in the art, and otherwise function as known in the art. Thus, an example DSSC as shown in FIG. 15 may be constructed according to the following: electrode layer 1506 (shown as fluorine-doped tin oxide, FTO) is deposited on a substrate layer 1507 (shown as glass). Mesoporous layer ML 1505 (which may in some embodiments be TiO₂) is deposited onto the electrode layer 1506, then the photoelectrode (so far comprising substrate layer 1507, electrode layer 1506, and mesoporous layer 1505) is soaked in a solvent (not shown) and dye 1504 comprising a photoactive compound of the present disclosure. This leaves the dye 1504 bound to the surface of the ML. A separate counter-electrode is made comprising substrate layer 1501 (also shown as glass) and electrode layer 1502 (shown as Pt/FTO). The photoelectrode and counter-electrode are combined, sandwiching the various layers 1502-1506 between the two substrate layers 1501 and 1507 as shown in FIG. 15, and allowing electrode layers 1502 and 1506 to be utilized as a cathode and anode, respectively. A layer of electrolyte 1503 is deposited either directly onto the completed photoelectrode after dye layer 1504 or through an opening in the device, typically a hole pre-drilled by sand-blasting in the counter-electrode substrate 1501. The cell may also be attached to leads and a discharge unit, such as a battery (not shown). Substrate layer 1507 and electrode layer 1506, and/or substrate layer 1501 and electrode layer 1502 should be of sufficient transparency to permit solar radiation to pass through to the photoactive dye 1504. In some embodiments, the counter-electrode and/or photoelectrode may be rigid, while in others either or both may be flexible. The substrate layers of various embodiments may comprise any one or more of: glass, polyethylene, PET, Kapton, quartz, aluminum foil, gold foil, and steel.

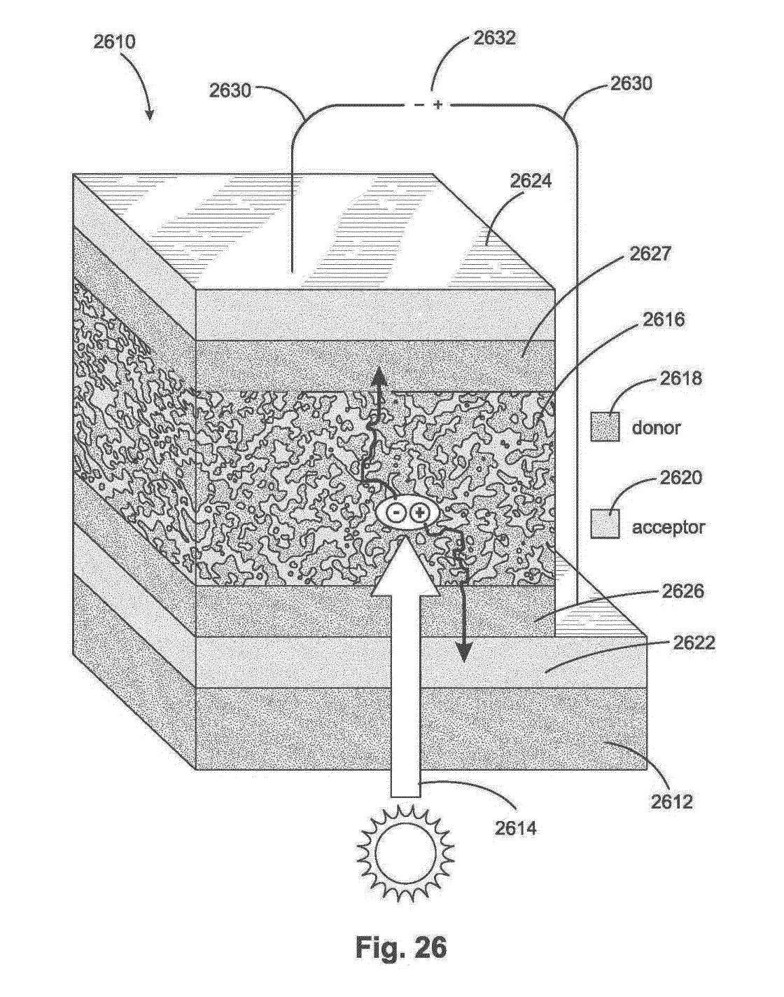

Other example embodiments may include a PV that comprises a photoactive layer comprising a photoactive compound of the present disclosure. Such embodiments may be described by reference to FIG. 26, which shows a typical PV cell 2610 including a transparent layer 2612 of glass (or material similarly transparent to solar radiation) which allows solar radiation 2614 to transmit through the layer. The transparent layer of some embodiments may also be referred to as a substrate, and it may comprise any one or more of a variety of rigid or flexible materials such as: glass, polyethylene, PET, Kapton, quartz, aluminum foil, gold foil, or steel. The photoactive layer 2616 is composed of electron donor or p-type material 2618 and electron acceptor or n-type material 2620. Compositions of the present disclosure may be used as either the p- or n-type material or both p- and n-type materials in a single device embodiment. The photo-active layer 2616 is sandwiched between two electrically conductive electrode layers 2622 and 2624. In FIG. 26, the electrode layer 2622 is an ITO material. The electrode layer 2624 is an aluminum material. Other materials may be used as is known in the art. The cell 2610 also includes an interfacial layer (IFL) 2626, shown as a PEDOT:PSS material. The IFL may assist in charge separation. In some embodiments, the IFL 2626 may comprise a tunable compound of the present disclosure as a self-assembled monolayer (SAM) or as a thin film instead of or in addition to the photoactive layer comprising a tunable compound of the present disclosure, as will be discussed in greater detail below. There also may be an IFL 2627 on the aluminum-cathode side of the device. In some embodiments, the IFL 2627 on the aluminum-cathode side of the device may comprise a tunable compound of the present disclosure as a self-assembled monolayer (SAM) or as a thin film instead of or in addition to either or both of the photoactive layer and the IFL 2626 comprising a tunable compound of the present disclosure, as will be discussed in greater detail below. An IFL according to some embodiments may be semiconducting in character, and may be either p-type or n-type. In some embodiments, the IFL on the cathode side of the device (e.g., IFL 2627 as shown in FIG. 26) may be p-type, and the IFL on the anode side of the device (e.g., IFL 2626 as shown in FIG. 26) may be n-type. In other embodiments, however, the cathode-side IFL may be n-type and the anode-side IFL may be p-type. The cell 2610 is attached to leads 2630 and a discharge unit 2632, such as a battery. An exemplary PV architecture according to some embodiments may be substantially of the form substrate-anode-IFL-active layer-IFL-cathode, wherein the active layer may comprise a tunable compound of the present disclosure. The active layer of some embodiments may be photoactive, and/or it may include photoactive material. Other layers and materials may be utilized in the cell as is known in the art. Furthermore, it should be noted that the use of the term “active layer” is in no way meant to restrict or otherwise define, explicitly or implicitly, the properties of any other layer—for instance, in some embodiments, either or both IFLs may also be active insofar as they may be semiconducting.

As noted, either or both of the IFLs (e.g., IFLs 2626 and 2627 as shown in FIG. 26) may comprise a tunable compound of the present disclosure as a self-assembled monolayer (SAM) or as a thin film. When a tunable compound of the present disclosure is applied as a SAM, it may comprise a binding group through which it may be covalently or otherwise bound to the surface of either or both of the anode and cathode. The binding group of some embodiments may comprise any one or more of COOH, SiX₃ (where X may be any moiety suitable for forming a ternary silicon compound, such as Si(OR)₃ and SiCl₃), SO₃, PO₄H, OH, CH₂X (where X may comprise a Group 17 halide), and O. The binding group may be covalently or otherwise bound to an electron-withdrawing moiety, an electron donor moiety, and/or a core moiety. The binding group may attach to the electrode surface in a manner so as to form a directional, organized layer of a single molecule (or, in some embodiments, multiple molecules) in thickness (e.g., where multiple tunable compounds are bound to the anode and/or cathode). As noted, the SAM may attach via covalent interactions, but in some embodiments it may attach via ionic, hydrogen-bonding, and/or dispersion force (i.e., Van Der Waals) interactions. Furthermore, in certain embodiments, upon light exposure, the SAM may enter into a zwitterionic excited state, thereby creating a highly-polarized IFL, which may direct charge carriers from an active layer into an electrode (e.g., either the anode or cathode). This enhanced charge-carrier injection may, in some embodiments, be accomplished by electronically poling the cross-section of the active layer and therefore increasing charge-carrier drift velocities towards their respective electrode (e.g., hole to anode; electrons to cathode). Molecules for anode applications of some embodiments may comprise tunable compounds that include a primary electron donor moiety bound to a core moiety, which in turn is bound to an electron-withdrawing moiety, which in turn is bound to a binding group. In cathode applications according to some embodiments, IFL molecules may comprise a tunable compound comprising an electron poor moiety bound to a core moiety, which in turn is bound to an electron donor moiety, which in turn is bound to a binding group. The tunable compound of such IFLs (whether cathode or anode IFLs) may be photoactive, although in some embodiments it need not be.

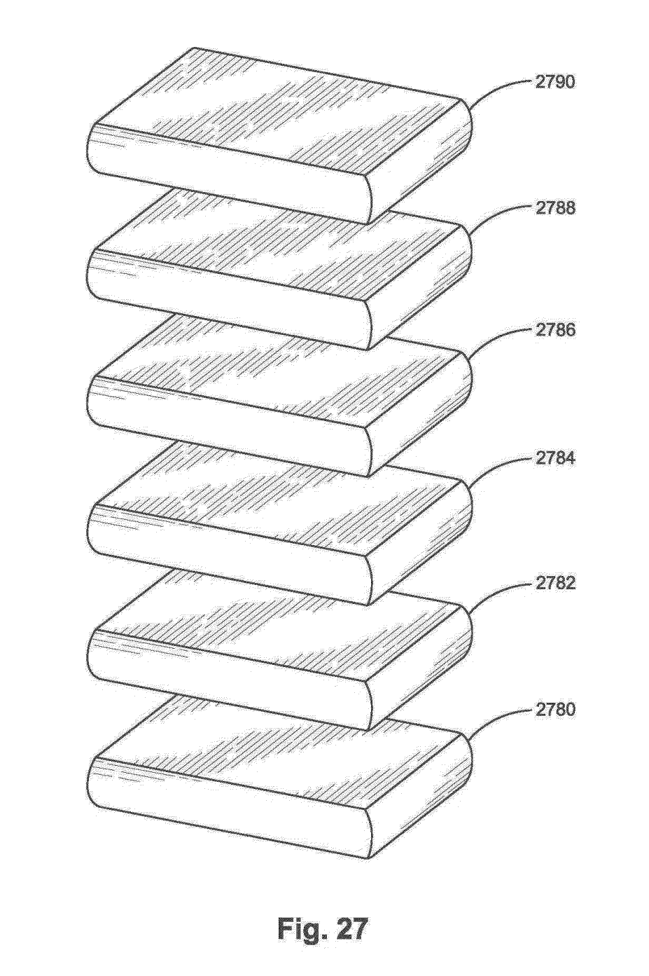

In other embodiments, the present disclosure provides hybrid organic-inorganic PVs comprising photoactive compounds of the present disclosure. FIG. 27 shows an exploded representational view of a sample PV cell having a transparent conducting electrode 2780, an electron blocking layer 2782, a p-type thin film active layer 2784, an n-type organic active layer 2786, a hole blocking layer 2788 and a low work function layer as an electrode 2790. As shown, the n-type organic layer comprises a photoactive compound of the present disclosure while the p-type layer is inorganic. In other embodiments, the p-type layer comprises a photoactive compound of the present disclosure while the n-type layer is inorganic.

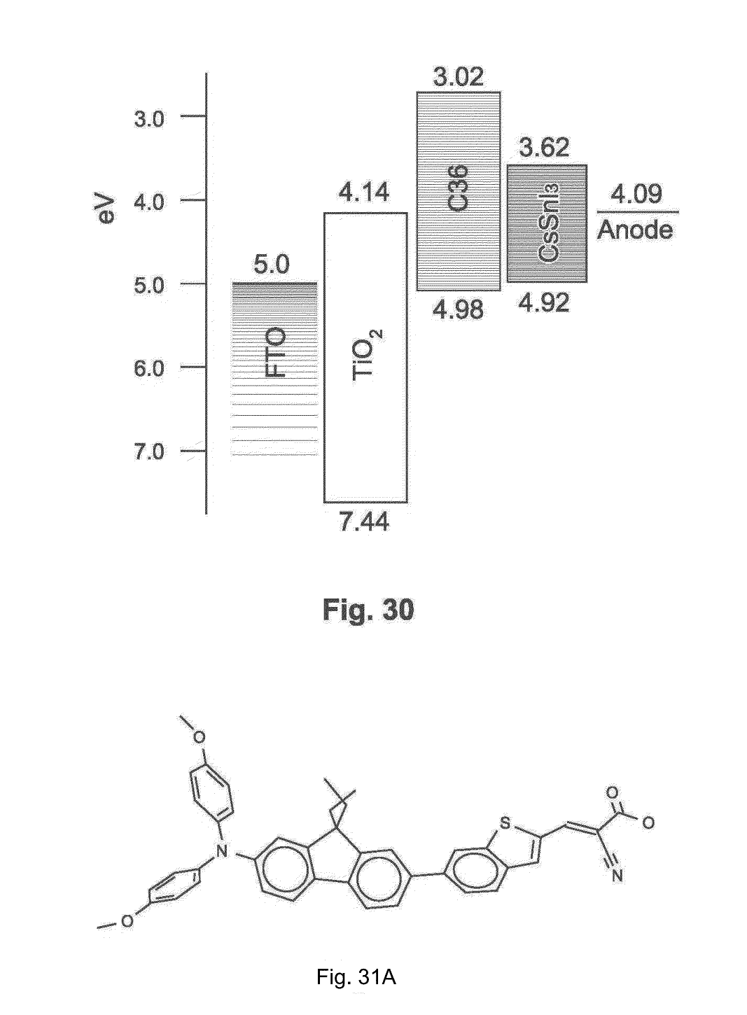

In other embodiments, the present disclosure provides solid state DSSCs. In some embodiments, the solid state DSSCs may comprise photoactive compounds according to some embodiments of the present disclosure. Employing a photoactive composition of the present disclosure in a solid state DSSC may, in some embodiments, significantly expand the freedom to design the photoactive composition. For instance, in some embodiments, a solid-state layer may advantageously permit a photoactive composition to obtain a shallower HOMO energy level while still maintaining electrical conductivity between the solid-state layer and the photoactive composition. FIG. 29 is a representation of relative energy levels in eV of various components of an exemplar solid state DSSC system that uses a solid-state layer (comprising in this example CsSnI₃). The data shown in FIG. 29 were derived from empirical results such as cyclic voltammetry or ultraviolet photoelectron spectroscopy. Comparison between FIG. 29 and FIG. 25 shows that the exemplar solid state DSSC of FIG. 29 uses the CsSnI₃ in place of the iodide electrolyte of FIG. 25. FIG. 29 shows the shallower HOMO energy level permitted by use of CsSnI₃ (4.92 eV as compared to the 5.34 eV value of iodide electrolyte reduction I₂⁻→I₃⁻). That is, the photoactive compound T2 of FIG. 29 could be altered (for example, by the design methods of the present disclosure previously discussed) so as to achieve a shallower HOMO, unlike the photoactive compound T2 of FIG. 25, where the relatively deeper eV value of the iodide electrolyte reduction I₂⁻→I₃⁻ provides an upper limit on the HOMO energy level of the photoactive compound T2, as explained previously. Alternatively, in other embodiments, a different photoactive compound consistent with the present disclosure may be used, wherein the different photoactive compound has a shallower HOMO energy level. For example, FIG. 30 shows a different photoactive compound C36 with a much shallower HOMO (4.98 eV) advantageously employed in the DSSC of this embodiment using a CsSnI₃ solid-state layer. The data shown in FIG. 30 were derived from empirical results such as cyclic voltammetry or ultraviolet photoelectron spectroscopy. FIG. 31A shows the structure of C36, which is (E)-2-cyano-3-[6-[9,9-diethyl-7-(4-methoxy-N-(4-methoxyphenyl)anilino)fluoren-2-yl]benzothiophen-2-yl]prop-2-enoic acid.

Solid-state DSSCs according to some embodiments may provide additional advantages. For instance, a solid-state DSSC may not experience leakage and/or corrosion issues that affect DSSCs comprising liquid electrolytes. Furthermore, a solid-state charge carrier may provide faster device physics (e.g., faster charge transport). Additionally, solid-state electrolytes may, in some embodiments, be photoactive and therefore contribute to power derived from a solid-state DSSC device.

Solid State DSSCs and Active Materials

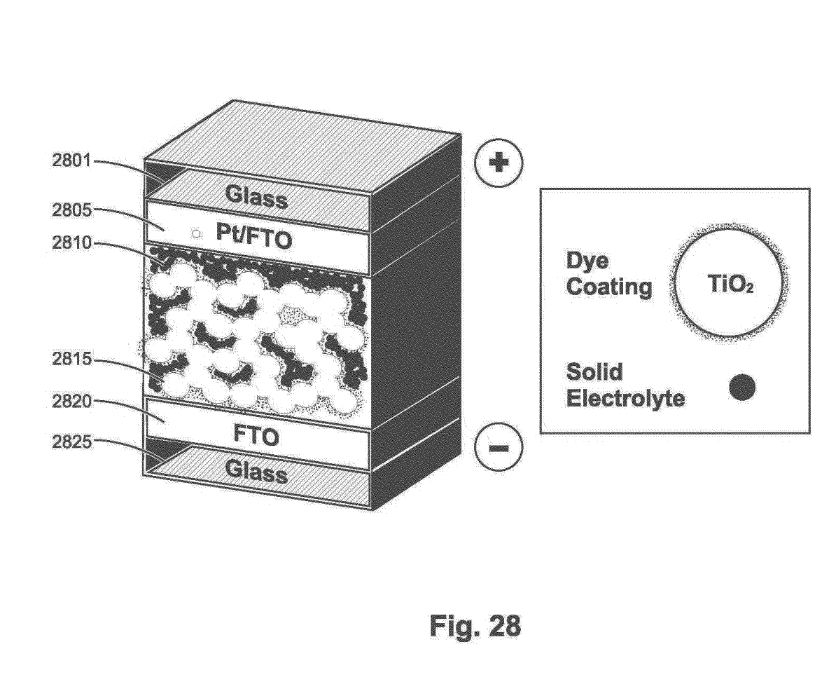

Some examples of solid state DSSCs may be described by reference to FIG. 28, which is a schematic of a typical solid state DSSC. As with the example solar cell depicted in, e.g., FIG. 26, an active layer comprised of first and second active (e.g., conducting and/or semi-conducting) material (2810 and 2815, respectively) is sandwiched between electrodes 2805 and 2820 (shown in FIG. 28 as Pt/FTO and FTO, respectively). In the embodiment shown in FIG. 28, the first active material 2810 is p-type active material, and comprises a solid electrolyte (otherwise known as a hole-transport material); the second active material 2815 is n-type active material and comprises TiO₂ coated with a dye. The dye may comprise a photoactive compound of the present disclosure. The second active material 2815 of some embodiments may constitute a mesoporous layer. Furthermore, in addition to being active, either or both of the first and second active materials 2810 and 2815 may be photoactive. In other embodiments (not shown in FIG. 28), the second active material may comprise a solid electrolyte. In addition, in embodiments where either of the first and second active material 2810 and 2815 comprise a solid electrolyte, the PV device may lack an effective amount of liquid electrolyte. Substrate layers 2801 and 2825 (both shown in FIG. 28 as glass) form the respective external top and bottom layers of the exemplar cell of FIG. 28. These layers may comprise any material of sufficient transparency to permit solar radiation to pass through to the active/photoactive layer comprising dye, first and second active and/or photoactive material 2810 and 2815, such as glass, polyethylene, PET, Kapton, quartz, aluminum foil, gold foil, and/or steel. Furthermore, in the embodiment shown in FIG. 28, electrode 2805 (shown as Pt/FTO) is the cathode, and electrode 2820 is the anode. As with the exemplar solar cell depicted in FIG. 26, solar radiation passes through substrate layer 2825 and electrode 2820 into the active layer, whereupon at least a portion of the solar radiation is absorbed so as to produce one or more excitons to enable electrical generation.

As noted, the first active material 2810 (which in FIG. 28 is, again, p-type) may in some embodiments comprise a solid electrolyte. In certain embodiments, the first active material 2810 may comprise an organic material such as spiro-OmeTAD and/or poly(3-hexylthiophene), an inorganic binary, ternary, quaternary, or greater complex, any solid semiconducting material, or any combination thereof. In some embodiments, the first active material may additionally or instead comprise an oxide such as a copper-oxide compound (as already noted), and/or a sulfide, and/or a selenide, and/or an iodide (e.g., CsSnI₃). Thus, for example, the first active material of some embodiments may comprise solid-state p-type material, which may comprise copper indium sulfide, and in some embodiments, it may comprise copper indium gallium selenide. In addition, as previously noted, the first active material may in some embodiments be photoactive (e.g., able to contribute to power derived from the DSSC). Furthermore, although shown and referred to in FIG. 28 as being p-type, a solid state layer (e.g., first active material comprising solid electrolyte) may in some embodiments instead be n-type semiconducting. In such embodiments, then, the second active material (e.g., TiO₂ (or other mesoporous material) as shown in FIG. 28) coated with a dye may be p-type semiconducting (as opposed to the n-type semiconducting shown in, and discussed with respect to, FIG. 28).

A copper-oxide compound may be referred to in the shorthand herein as Cu₂O and/or cuprous oxide. Although so labeled, such references are not intended to limit the ratio of copper and oxygen of the various copper oxide compounds according to various embodiments. Some embodiments may instead or in addition include various stoichiometric ratios of copper and oxygen, which may be stoichiometric and/or non-stoichiometric. For example, a copper oxide compound according to some embodiments may comprise copper having any one or more oxidation states (e.g., copper 0, copper I, copper II, and mixtures thereof). The ratios of copper and oxide in such compounds would therefore depend upon the oxidation state(s) of the copper atoms present. Thus, some embodiments may include any one or more copper-oxide compounds, each having a ratio of CuₓO_{y}. In such embodiments, x may be any value, integer or non-integer, between 1 and 100. In some embodiments, x may be between approximately 1 and 3 (and, again, need not be an integer). Likewise, y may be any value, integer or non-integer, between 0.1 and 100. In some embodiments, y may be between approximately 0.1 and 2 (and, again, need not be an integer). Thus, for example, although embodiments discussed herein may include Cu₂O (e.g., x=2 and y=1), other embodiments may instead or in addition include any of Cu_{2.1}O_{0.9}, CuO, Cu₃O_{0.1}, Cu₄₇O_{23.5}, and any other ratio in accordance with the foregoing.

Similarly, references in some exemplar embodiments herein to CsSnI₃ are not intended to limit the ratios of component elements in the cesium-tin-iodine compounds according to various embodiments. Some embodiments may include stoichiometric and/or non-stoichiometric amounts of tin and iodide, and thus such embodiments may instead or in addition include various ratios of cesium, tin, and iodine, such as any one or more cesium-tin-iodine compounds, each having a ratio of CsₓSn_{y}I_{z}. In such embodiments, x may be any value, integer or non-integer, between 0.1 and 100. In some embodiments, x may be between approximately 0.5 and 1.5 (and, again, need not be an integer) Likewise, y may be any value, integer or non-integer, between 0.1 and 100. In some embodiments, y may be between approximately 0.5 and 1.5 (and, again, need not be an integer). Likewise, z may be any value, integer or non-integer, between 0.1 and 100. In some embodiments, z may be between approximately 2.5 and 3.5. Additionally CsSnI₃ can be doped or compounded with other materials, such as SnF₂, in ratios of CsSnI₃:SnF₂ ranging from 0.1:1 to 100:1, including all values (integer and non-integer) in between.

Furthermore, references herein to TiO₂ and/or titania are likewise not intended to limit the ratios of tin and oxide in such tin-oxide compounds described herein. That is, a titania compound may comprise titanium in any one or more of its various oxidation states (e.g., titanium I, titanium II, titanium III, titanium IV), and thus various embodiments may include stoichiometric and/or non-stoichiometric amounts of titanium and oxide. Thus, various embodiments may include (instead or in addition to TiO₂) TiₓO_{y}, where x may be any value, integer or non-integer, between 1 and 100. In some embodiments, x may be between approximately 0.5 and 3. Likewise, y may be between approximately 1.5 and 4 (and, again, need not be an integer). Thus, some embodiments may include, e.g., TiO₂ and/or Ti₂O₃. In addition, titania in whatever ratios or combination of ratios between titanium and oxide may be of any one or more crystal structures in some embodiments, including any one or more of anatase, rutile, and amorphous.

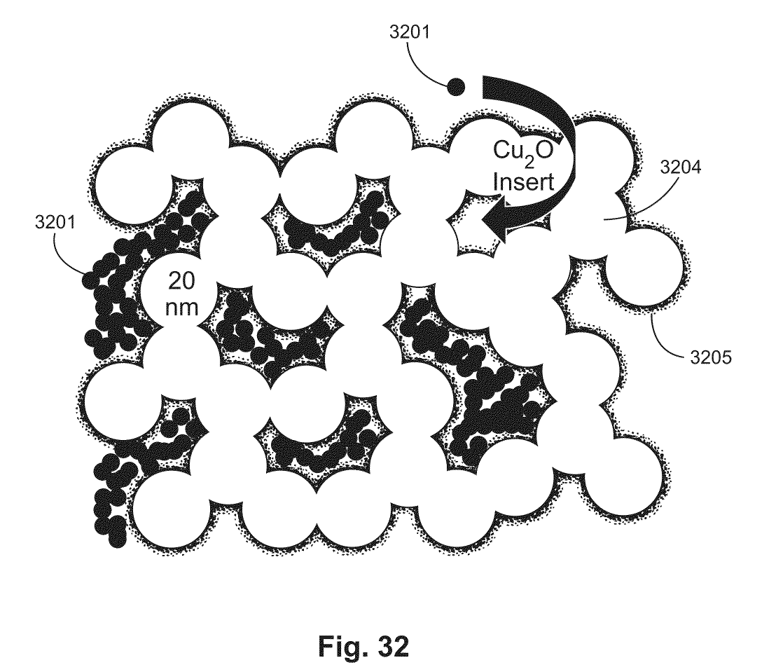

Returning to DSSCs, in some embodiments, the first active material 2810 may comprise nanoparticles (e.g., Cu₂O nanoparticles and/or CsSnI₃ nanoparticles and/or copper indium sulfide nanoparticles). In some embodiments, the nanoparticles may be 50 nm or less in diameter (assuming spherical approximation, although the nanoparticles of some embodiments may not necessarily be spherical). In other embodiments, the nanoparticles' diameters may be 20 nm or less, 10 nm or less, or 5 nm or less, respectively. The first active material nanoparticles of some embodiments may be interposed, interpenetrating, or otherwise inserted within or among the second active material (e.g., within or among a mesoporous layer comprising the second active material). For example, referring to FIG. 32, one or more p-type active nanoparticles 3201 (shown as Cu₂O nanoparticles in FIG. 32) may be interposed among a TiO₂ matrix 3204 (or other second active material) coated with a dye 3205. As shown in FIG. 32, the second active material mesoporous layer comprises TiO₂ particles 3204 of approximately 20 nm diameter in a matrix.

Nanoparticles of Cu₂O as shown in FIG. 32 may be prepared, for example, by making a suspension of Cu₂O nanoparticles via reaction of a Cu(I) starting material (e.g., cuprous acetate, or any other starting material wherein Cu(I) would disassociate from that material) with an amine (e.g., propylamine, or any other reactive amine) in aqueous solution. As noted, although referred to in FIG. 32 as p-type active nanoparticles 3201, in some embodiments the active nanoparticles 3201 may instead be n-type (and the TiO₂ matrix or other mesoporous layer material may be n-type or p-type).

In some embodiments of solid-state DSSCs, the second active material (again, shown as n-type TiO₂ 2815 in FIG. 28) may likewise comprise an organic material such as spiro-OMeTAD, an inorganic binary, ternary, quaternary, or greater complex, or any combination thereof. In some embodiments, the second active material may comprise an oxide such as alumina and/or cuprous oxide; and/or it may comprise a sulfide; and/or it may comprise a selenide. Thus, in some embodiments, the second active material may comprise copper indium sulfide, and in some embodiments, it may comprise copper indium gallium selenide metal oxide.

In yet other embodiments, either or both of the first and second active material (e.g., active materials 2810 and 2815 of FIG. 28) may comprise a perovskite material that is, a material of the general formula CMX₃, where: C comprises one or more cations (e.g., an amine, ammonium, a Group 1 metal, a Group 2 metal, and/or other cations or cation-like compounds); M comprises one or more metals (exemplars including Fe, Co, Ni, Cu, Sn, Pb, Bi, Ge, Ti, and Zr); and X comprises one or more anions. In some embodiments, C may include one or more organic cations, and X may include one or more halides. In certain embodiments, X may instead or in addition include any Group 16 anion. In some embodiments, each organic cation C may be larger than each metal M, and each anion X may be capable of bonding with both a cation C and a metal M. Examples of perovskite material suitable for inclusion in either or both of the first and second active material include the aforementioned CsSnI₃ (in some embodiments, in ratios of CsₓSn_{y}I_{z}, with x, y, and z varying in accordance with the previous discussion). Other examples include compounds of the general formula CsSnX₃, where X may be any one or more of: I₃, I_{2.95}F_{0.05}; I₂Cl; ICl₂; and Cl₃. In other embodiments, X may comprise any one or more of I, Cl, F, and Br in amounts such that the total ratio of X as compared to Cs and Sn results in the general stoichiometry of CsSnX₃. In some embodiments, the combined stoichiometry of the elements that constitute X may follow the same rules as I_{z} as previously discussed with respect to CsₓSn_{y}I_{z}. Yet other examples include compounds of the general formula RNH₃PbX₃, where R may be CₙH₂ₙ₊₁, with n ranging from 0-10, and X may include any one or more of F, Cl, Br, and I in amounts such that the total ratio of X as compared to the cation RNH₃ and metal Pb results in the general stoichiometry of RNH₃PbX₃. Further, some specific examples of R include H, and alkyl chains (e.g., CH₃, CH₃CH₂, CH₃CH₂CH₂, and so on). As with other active material types, a first and/or second active material comprising perovskite material may be employed in conjunction with a tunable compound (e.g., a tunable compound dye) of the present disclosure in a solid state DSSC. In certain embodiments, a perovskite material may be employed as a dye (e.g., dye 1504); and/or as active material in a BHJ (e.g., IFL 2403 and/or photoactive layer 2404).

A solid state DSSC according to some embodiments may be constructed in a substantially similar manner to that described above with respect to the DSSC depicted as stylized in FIG. 15. In the embodiment shown in FIG. 28, p-type active material 2810 corresponds to electrolyte 1503 of FIG. 15; n-type active material 2815 corresponds to both dye 1504 and ML 1505 of FIG. 15; electrodes 2805 and 2820 respectively correspond to electrode layers 1502 and 1506 of FIG. 15; and substrate layers 2801 and 2825 respectively correspond to substrate layers 1501 and 1507.

A first (e.g., p-type) active material (e.g., Cu₂O nanoparticles 3205) of some embodiments may advantageously be deployed in either organic or non-organic DSSCs; that is, in some embodiments, a tunable photoactive compound might not be necessary in order to realize some performance improvement in a DSSC comprising a p-type active material such as Cu₂O nanoparticles. For example, Cu₂O nanoparticles may be employed with any adsorbed dye known in the art (e.g., N719, N3, which may be colloquially referred to as “black dye”) in order to realize performance gains over the otherwise identical DSSCs without a p-type active material according to some embodiments of the present disclosure. In other embodiments, performance improvements may be realized without the use of any dye, e.g., a device containing only Cu₂O and TiO₂ nanoparticles as the active layer.

Nonetheless, in other embodiments, various advantages (e.g., performance improvements, cost reduction, and/or efficiency gains) may result from inclusion of both a semi-conducting active material of some embodiments and a tunable photoactive compound of some embodiments.

Thin-Coat IFLs

In addition, at least a portion of either the first or the second active material of some embodiments may be coated with a thin interfacial layer (a “thin-coat interfacial layer” or “thin-coat IFL”). And, in turn, at least a portion of the thin-coat IFL may be coated with a dye. The thin-coat IFL may be either n- or p-type; in some embodiments, it may be of the same type as the underlying material (e.g., TiO₂ or other mesoporous material, such as TiO₂ of second active material 2815). The second active material may comprise TiO₂ coated with a thin-coat IFL comprising alumina (e.g., Al₂O₃) (not shown in FIG. 28), which in turn is coated with a dye. Other exemplar metal oxides for use in the thin-coat IFL of some embodiments may include semiconducting metal oxides, such as NiO, WO₃, V₂O₅, or MoO₃. The exemplar embodiment wherein the second (e.g., n-type) active material comprises TiO₂ coated with a thin-coat IFL comprising Al₂O₃ could be formed, for example, with a precursor material such as Al(NO₃)₃.xH₂O, or any other material suitable for depositing Al₂O₃ onto the TiO₂, followed by thermal annealing and dye coating. In example embodiments wherein a MoO₃ coating is instead used, the coating may be formed with a precursor material such as Na₂Mo₄.2H₂O; whereas a V₂O₅ coating according to some embodiments may be formed with a precursor material such as NaVO₃; and a WO₃ coating according to some embodiments may be formed with a precursor material such as NaWO₄.H₂O. The concentration of precursor material (e.g., Al(NO₃)₃.xH₂O) may affect the final film thickness (here, of Al₂O₃) deposited on the TiO₂ or other active material. Thus, modifying the concentration of precursor material may be a method by which the final film thickness may be controlled. For example, greater film thickness may result from greater precursor material concentration. Greater film thickness may not necessarily result in greater PCE in a PV device comprising a metal oxide coating. Thus, a method of some embodiments may include coating a TiO₂ (or other mesoporous) layer using a precursor material having a concentration in the range of approximately 0.5 to 10.0 mM; other embodiments may include coating the layer with a precursor material having a concentration in the range of approximately 2.0 to 6.0 mM; or, in other embodiments, approximately 2.5 to 5.5 mM.

Furthermore, although referred to herein as Al₂O₃ and/or alumina, it should be noted that various ratios of aluminum and oxygen may be used in forming alumina. Thus, although some embodiments discussed herein are described with reference to Al₂O₃, such description is not intended to define a required ratio of aluminum in oxygen. Rather, embodiments may include any one or more aluminum-oxide compounds, each having an aluminum oxide ratio according to AlₓO_{y}, where x may be any value, integer or non-integer, between approximately 1 and 100. In some embodiments, x may be between approximately 1 and 3 (and, again, need not be an integer). Likewise, y may be any value, integer or non-integer, between 0.1 and 100. In some embodiments, y may be between 2 and 4 (and, again, need not be an integer). In addition, various crystalline forms of AlₓO_{y} may be present in various embodiments, such as alpha, gamma, and/or amorphous forms of alumina.

Likewise, although referred to herein as MoO₃, WO₃, and V₂O₅, such compounds may instead or in addition be represented as MoₓO_{y}, WₓO_{y}, and VₓO_{y}, respectively. Regarding each of MoₓO_{y} and WₓO_{y}, x may be any value, integer or non-integer, between approximately 0.5 and 100; in some embodiments, it may be between approximately 0.5 and 1.5. Likewise, y may be any value, integer or non-integer, between approximately 1 and 100. In some embodiments, y may be any value between approximately 1 and 4. Regarding VₓO_{y}, x may be any value, integer or non-integer, between approximately 0.5 and 100; in some embodiments, it may be between approximately 0.5 and 1.5. Likewise, y may be any value, integer or non-integer, between approximately 1 and 100; in certain embodiments, it may be an integer or non-integer value between approximately 1 and 10.

In addition, a thin-coat IFL may comprise a bilayer. Thus, returning to the example wherein the thin-coat IFL comprises a metal-oxide (such as alumina), the thin-coat IFL may comprise TiO₂-plus-metal-oxide. Such a thin-coat IFL may have a greater ability to resist charge recombination as compared to mesoporous TiO₂ or other active material alone. Furthermore, in forming a TiO₂ layer, a secondary TiO₂ coating is often necessary in order to provide sufficient physical interconnection of TiO₂ particles, according to some embodiments of the present disclosure. Coating a bilayer thin-coat IFL onto mesoporous TiO₂ (or other mesoporous active material) may comprise a combination of coating using a compound comprising both metal oxide and TiCl₄, resulting in an bilayer thin-coat IFL comprising a combination of metal-oxide and secondary TiO₂ coating, which may provide performance improvements over use of either material on its own. For instance, as shown in Table 5, coating a mesoporous layer included in a conventional DSSC device (i.e., one using a liquid electrolyte and common dye N719) with a bilayer thin-coat IFL consisting of depositing a TiO₂ thin film followed by heating (denoted in Table 5 as TiCl₄—H) and then depositing an Al₂O₃ thin film followed by further heating (denoted as Alumina-H) results in an improved PCE of 7.9. Use of metal oxide and other thin-coat IFLs in embodiments other than those comprising solid-state DSSCs with dyes that include a photoactive organic compound are discussed infra. In the context of embodiments employing a dye comprising a photoactive organic compound, and/or a solid-state DSSC of embodiments of the present disclosure, one of ordinary skill in the art would expect similar improvement to that shown in Table 5 for more conventional liquid electrolyte DSSCs.

TABLE 5

| Coating | V_{OC} (V) | J_{SC} (mA/cm²) | FF (%) | PCE (%) |
|---|---|---|---|---|
| No coating | 0.73 | 7.77 | 66.0 | 4.50 |
| Alumina | 0.73 | 5.90 | 72.60 | 3.80 |
| TiCl₄ | 0.74 | 13.50 | 60.00 | 7.20 |
| TiCl₄ + Alumina | 0.76 | 10.40 | 67.00 | 6.40 |
| TiCl₄—H + | 0.77 | 12.00 | 70.10 | 7.90 |
| Alumina-H | | | | |

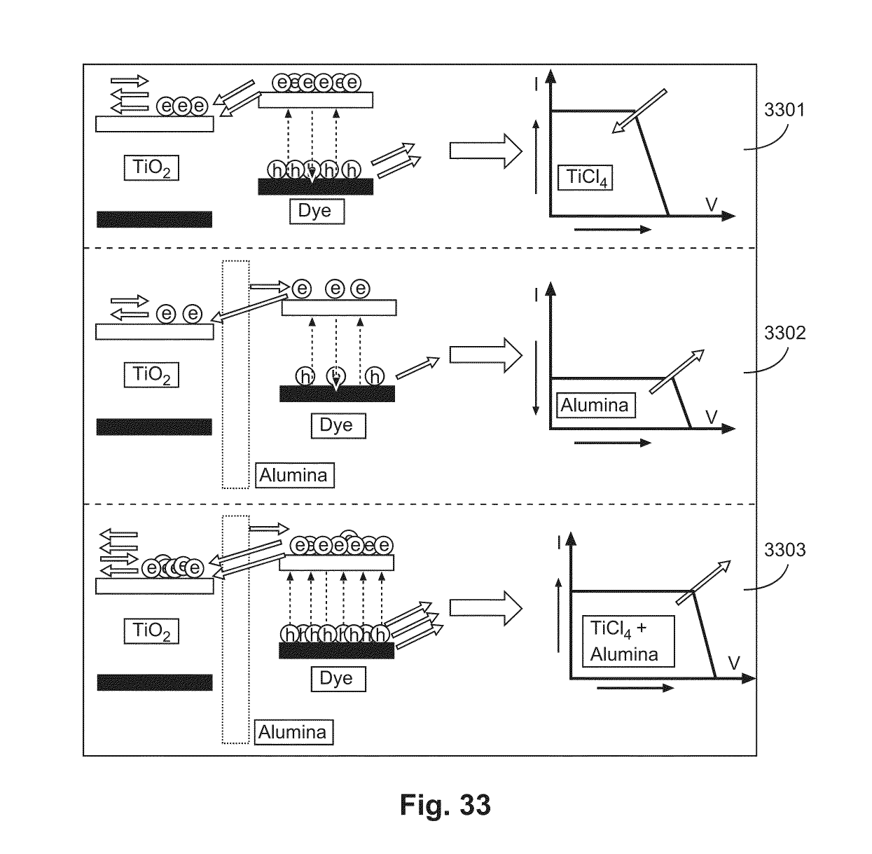

Furthermore, some advantages of a bilayer thin-coat IFL according to some embodiments, including some of the advantages discussed above, may be shown by reference to FIG. 33. FIG. 33 is a series of three stylizations that depict differences in resistance of charge recombination in three architectures 3301, 3302, and 3303 as follows: (3301) TiO₂ coated with a dye in the absence of a metal oxide interfacial layer; (3302) TiO₂ coated with alumina as previously described for some embodiments; and (3303) TiO₂ coated with a thin-film bilayer of TiO₂ and Al₂O₃ in the architecture meso-TiO₂/TiO₂/Al₂O₃). In a DSSC device according to the architecture depicted in 3301, a TiO₂ mesoporous layer is further coated with a TiO₂ thin film, followed by thermal annealing, to allow for continuous contact between individual TiO₂ nanoparticles. In this scenario, electron back-injection is possible where electrons contained within TiO₂ may recombine with oxidized dye molecules, annihilating a charge carrier pair and reducing V_{oc} values as shown in the chart associated with first architecture 3301. When Al₂O₃ replaces TiO₂ in the thin film (architecture 3302), an effective interfacial layer for preventing charge recombination may be formed, thereby resulting in enhanced V_{oc} values as shown in the chart associated with architecture 3302; however, Al₂O₃ alone may form a resistive interface preventing conductive electron collection, which would thereby result in reduced I_{sc} values as shown in the chart associated with architecture 3302. In the final depicted architecture (3303), a TiO₂ mesolayer is coated with a TiO₂ thin film followed by thermal annealing, and then a second interfacial layer of Al₂O₃ is applied to the underlying TiO₂ interfacial layer, forming a TiO₂/Alumina bilayer. In doing so, charge recombination may be prevented, but this may form a layer less resistive to charge collection. The final result is enhanced V_{oc} values with minimal I_{sc} losses (as shown in the chart associated with architecture 3303), as compared to a DSSC device of either of the previously discussed architectures 3301 and 3302, as well as greater shunt resistance (Rₛₕ) with minimal increases in series resistance (Rₛ).

The thin-coat IFLs and methods of coating them onto TiO₂ previously discussed may, in some embodiments, be employed in DSSCs comprising liquid electrolytes (as alluded to in Table 5 above). Thus, returning to the example of a thin-coat IFL and referring back to FIG. 15 for an example, the DSSC of FIG. 15 could further comprise a thin-coat IFL as described above coated onto the mesoporous layer 1505 (that is, the thin-coat IFL would be inserted between mesoporous layer 1505 and dye 1504). Likewise, the ML of FIG. 16 could be coated with a thin-coat IFL as described above, thus leaving a thin-coat IFL (e.g., a bilayer thin-coat IFL, or a metal-oxide thin-coat IFL) between ML 1505 and light-harvesting layer 1601 of FIG. 16. In addition, thin-coat IFLs (such as those comprising metal oxides) may be advantageously employed either with a dye comprising a photoactive organic compound according to some embodiments of the present disclosure, or they may (like the semiconducting active material of some embodiments) be employed with a conventional dye, such as N719, which is known in the art.

In some embodiments, the thin-coat IFLs previously discussed in the context of DSSCs may be used in any interfacial layer of a semiconductor device such as a PV (e.g., a hybrid PV or other PV), a battery, field-effect transistor, light-emitting diode, non-linear optical device, memristor, capacitor, rectifier, rectifying antenna, etc. Furthermore, thin-coat IFLs of some embodiments may be employed in any of various devices in combination with other compounds discussed in the present disclosure, including but not limited to any one or more of the following of various embodiments of the present disclosure: tunable photoactive compounds; solid hole-transport material such as active material (e.g., active material including Cu₂O nanoparticles); and additives (such as, in some embodiments, chenodeoxycholic acid or 1,8-diiodooctane).

Other Improved Interfacial Layers

In addition, the present disclosure in some embodiments provides interfacial layers comprising treated asphaltene. Such interfacial layers may likewise be used in any suitable semiconductor device such as any one or more of the PVs discussed herein (including, but not limited to, DSSCs, BHJs, and hybrid PVs), a battery, field-effect transistors, LEDs, etc. In some embodiments, treated asphaltene interfacial layers may be formed by a process comprising: extracting asphaltenes from crude oil; casting the asphaltenes onto a substrate; and heating the asphaltenes in the presence of oxygen (which may be, e.g., in open air). Asphaltenes may be extracted from crude oil by any extraction process known in the art. Casting the asphaltenes onto a substrate may in some embodiments comprise casting the asphaltenes as thin films from a suitable solution, for example by spin coating, blade coating, spray coating, or other similar methods. For example, spin coating may be carried out at 3000 rpm for about 30 seconds in some embodiments, though in other embodiments, the asphaltenes in solution may be spin coated at speeds ranging from about 100 rpm to about 10,000 rpm, and over a time period ranging from about 1 second to about 5 minutes. Suitable solutions for coating the asphaltenes may include, but are not limited to, chlorobenzene solutions, dicholorbenzene solutions, toluene solutions, and chloroform solutions. The substrate may, in some embodiments, be a component of a PV or other electronic device. For example, in embodiments where the interfacial layer comprising treated asphaltene is employed in a BHJ device (as depicted, e.g., in FIG. 24B), the asphaltene in solution may be coated on an electrode of the BHJ device that comprises, in some embodiments, ITO (e.g., ITO electrode 2402). In such embodiments, then, interfacial layer 2403 of the BHJ device would accordingly comprise treated asphaltenes.

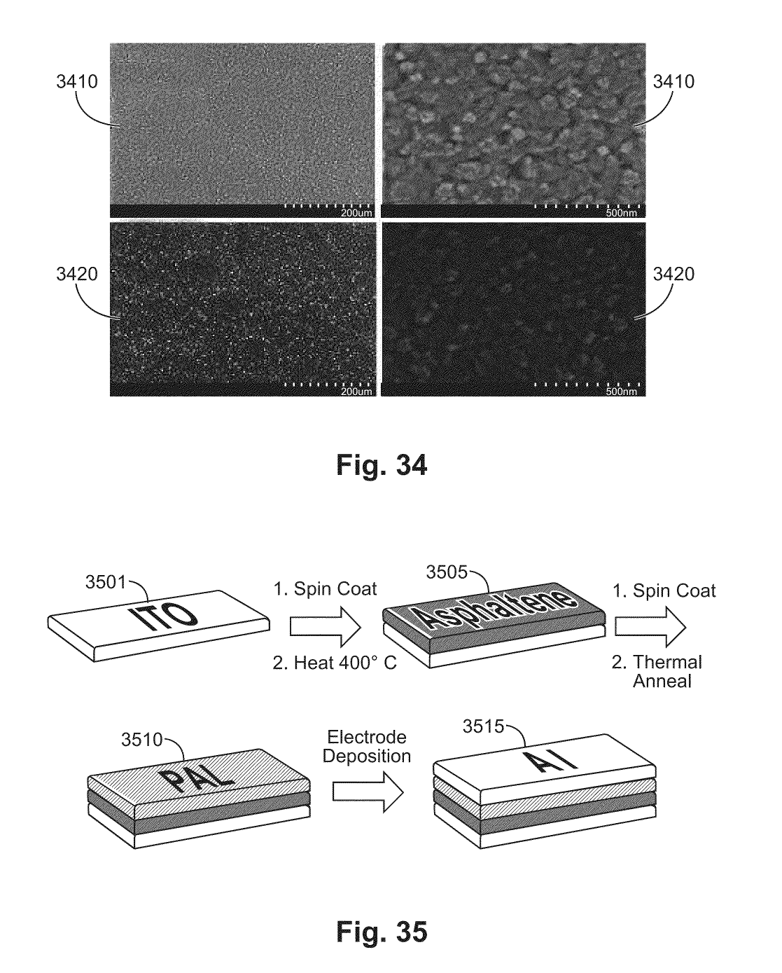

In some embodiments, heating the asphaltenes in open air may include annealing the asphaltenes in open air after coating. Suitable temperatures for annealing may include a temperature ranging from about 50° C. to about 1000° C.; in some embodiments, annealing may take place at about 300° C. to about 400° C.; in other embodiments, annealing may take place at about 20° C. to about 600° C. In some embodiments, heating may take place for an amount of time from about 1 second to about 24 hours; in other embodiments, heating may take place for about 5 to about 15 minutes, or for about 10 minutes in other embodiments. In some embodiments, annealing may lead to reactions with oxygen in the air and intermolecular crosslinking among asphaltene compounds, thereby forming insoluble films at the surface of the asphaltenes. These insoluble films may allow for subsequent solvent deposition without risk of washing away the underlying interfacial layer comprising the treated asphaltenes. FIG. 34 shows images of asphaltene films heated in air for 10 minutes at 300° C. (both low magnification 3405 and high magnification 3410) and 400° C. (both low magnification 3415 and high magnification 3420). The films were observed under scanning electron microscopy, and demonstrated a distinct island nanostructure that, at d=50 nm, reflects the underlying substrate (here, ITO) grain structure.

An example process of forming a treated asphaltene interfacial layer according to some embodiments of the present disclosure is set out in FIG. 35. Asphaltenes in solution are spin-coated onto a substrate 3501 (here, ITO electrode pre-treated for 10 minutes in a UV-ozone reactor, plasma reactor, or a solvent such as acetone, isopropanol, or toluene) and heated to 400° C., leaving a treated asphaltene layer 3505 on the substrate 3501. A photoactive layer (PAL) 3510 is spin-coated onto the treated asphaltene layer 3505 and thermally annealed, followed by electrode deposition of an electrode 3515 (here, aluminum) onto the PAL 3510. When this or other processes in accordance with various embodiments of the present disclosure are carried out on, e.g., a BHJ, the substrate 3501 corresponds to glass substrate 2401 and ITO electrode 2402 of FIG. 24B; the PAL 3510 corresponds to photoactive layer 2404; and electrode 3515 corresponds to cathodes 2405.

In some embodiments, an interfacial layer comprising treated asphaltenes may be employed in other device types, such as hybrid PVs, DSSCs (both solid-state and liquid electrolyte), and other electronic devices, including but not limited to: field-effect transistors, light-emitting diodes, non-linear optical devices, memristors, capacitors, rectifiers, and/or rectifying antennas. For example, a treated asphaltene interfacial layer may in some embodiments be deposited onto a counterelectrode in lieu of, for example, platinum, in a DSSC (either solid-state or liquid electrolyte) in accordance with any suitable asphaltene interfacial layer deposition method discussed herein. In addition, in some embodiments, a thin-coat IFL may include treated asphaltenes. Thus, returning to the example DSSC of FIG. 28, the second active material 2815 may be coated with a thin-coat IFL including treated asphaltenes, which in turn is coated with a dye. And in other embodiments where treated asphaltenes are employed in liquid electrolyte type DSSCs, the exemplar DSSCs of FIG. 15 or FIG. 16 would further include a treated asphaltene thin-coat IFL coated on top of the mesoporous layer 1505, wherein coating of the treated asphaltene may take place by any suitable method in accordance with the present disclosure.

Furthermore, treated asphaltene interfacial layers may in some embodiments be employed in any of various devices in combination with other compounds discussed in the present disclosure, including but not limited to any one or more of the following of various embodiments of the present disclosure: tunable photoactive compounds; solid hole-transport material such as p-type active material (e.g., p-type material including Cu₂O nanoparticles); and additives (such as, in some embodiments, chenodeoxycholic acid or 1,8-diiodooctane).

Other Exemplar Electronic Devices

As already mentioned, in some embodiments, a tunable photoactive compound may be included in any of a variety of electronic devices. Another example of such is a monolithic thin-film PV and battery device, or hybrid PV battery.

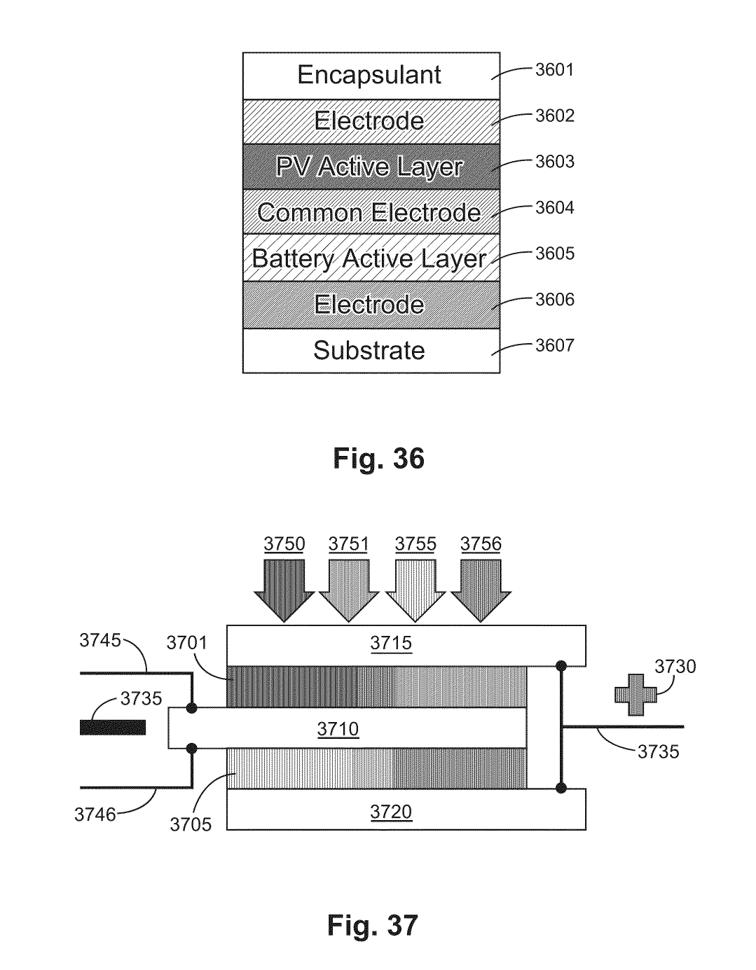

A hybrid PV battery according to some embodiments of the present disclosure may generally include a PV cell and a battery portion sharing a common electrode and electrically coupled in series or parallel. For example, hybrid PV batteries of some embodiments may be described by reference to FIG. 36, which is a stylized diagram of components of an exemplar hybrid PV battery, and includes: an encapsulant 3601; at least three electrodes 3602, 3604, and 3606, at least one of which is a common electrode (here 3604) shared by the PV portion of the device and the battery portion of the device; a PV active layer 3603; a battery active layer 3605; and a substrate 3607. In such example embodiments, the PV cell of the device may comprise one electrode 3602 (which may in some embodiments be referred to as a PV electrode) and the PV active layer 3603, while the battery of the device may comprise the other non-shared electrode 3606 (which may in some embodiments be referred to as a battery electrode) and the battery active layer 3605. The PV cell and the battery portion of such embodiments share the common electrode 3604. In some embodiments, the hybrid PV battery may be monolithic, that is, imprinted on a single substrate. In such embodiments, both the PV cell and the battery portion should be thin-film type devices. In some embodiments, both the PV cell and the battery may be capable of being printed by high-throughput techniques such as ink-jet, die-slot, gravure, and imprint roll-to-roll printing.

The PV cell of some embodiments may include a DSSC, a BHJ, a hybrid PV, or any other PV known in the art, such as cadmium telluride (CdTe) PVs, or CIGS (copper-indium-gallium-selenide) PVs. For example, in embodiments where the PV cell of a hybrid PV battery comprises a DSSC, the PV cell may be described by comparison between the exemplar liquid electrolyte DSSC of FIG. 15 and the PV cell of the exemplar hybrid PV battery of FIG. 36. Specifically, PV electrode 3602 may correspond to electrode layer 1502; PV active layer 3603 may correspond to electrolyte 1503, dye 1504, and ML 1505; and common electrode 3604 may correspond to electrode layer 1506. Any other PV may similarly correspond to the PV cell components of some embodiments of a hybrid PV battery, as will be apparent to one of ordinary skill in the art with the benefit of this disclosure. Furthermore, as with the PV devices discussed herein, the PV active layer within the PV cell of the device may in some embodiments comprise any one or more of: a treated asphaltene interfacial layer; first and/or second active material (each of which may be n-type or p-type semiconducting, and either or both of which may include a metal-oxide interfacial layer according to various embodiments discussed herein); and a tunable photoactive compound.

The battery portion of such devices may be composed according to batteries known in the art, such as lithium ion or zinc air. In some embodiments, the battery may be a thin-film battery.

Thus, for example, a hybrid PV battery according to some embodiments may include a DSSC integrated with a zinc-air battery. Both devices are thin-film type and are capable of being printed by high-throughput techniques such as ink-jet roll-to-roll printing, in accordance with some embodiments of the present disclosure. In this example, the zinc-air battery is first printed on a substrate (corresponding to substrate 3607) completed with counter-electrode. The battery counter-electrode then becomes the common electrode (corresponding to common electrode 3604) as the photoactive layer (corresponding to PV active layer 3603) is subsequently printed on the electrode 3604. The device is completed with a final electrode (corresponding to PV electrode 3602), and encapsulated in an encapsulant (corresponding to encapsulant 3601). The encapsulant may comprise epoxy, polyvinylidene fluoride (PVDF), ethyl-vinyl acetate (EVA), Parylene C, or any other material suitable for protecting the device from the environment.

In some embodiments, a hybrid PV battery may provide several advantages over known batteries or PV devices. In embodiments in which the hybrid PV battery is monolithic, it may exhibit increased durability due to the lack of connecting wires. The combination of two otherwise separate devices into one (PV and battery) further may advantageously reduce overall size and weight compared to use of a separate PV to charge a separate battery. In embodiments in which the hybrid PV battery comprises a thin-film type PV cell and battery portion, the thin-type PV cell may advantageously be capable of being printed in-line with a battery on substrates known to the battery industry, such as polyimides (e.g., Kapton or polyethylene terephthalate (PET)). In addition, the final form factor of such hybrid PV batteries may, in some embodiments, be made to fit form factors of standard batteries (e.g., for use in consumer electronics, such as coin, AAA, AA, C, D, or otherwise; or for use in, e.g., cellular telephones). In some embodiments, the battery could be charged by removal from a device followed by placement in sunlight. In other embodiments, the battery may be designed such that the PV cell of the battery is externally-facing from the device (e.g., the battery is not enclosed in the device) so that the device may be charged by exposure to sunlight. For example, a cellular telephone may comprise a hybrid PV battery with the PV cell of the battery facing the exterior of the phone (as opposed to placing the battery entirely within a covered portion of the phone).

In addition, some embodiments of the present disclosure may provide a multi-photoactive-layer PV cell. Such a cell may include at least two photoactive layers, each photoactive layer separated from the other by a shared double-sided conductive (i.e., conductor/insulator/conductor) substrate. The photoactive layers and shared substrate(s) of some embodiments may be sandwiched between conducting layers (e.g., conducting substrates, or conductors bound or otherwise coupled to a substrate). In some embodiments, any one or more of the conductors and/or substrates may be transparent to at least some electromagnetic radiation within the UV, visible, or IR spectrum.

Each photoactive layer may have a makeup in accordance with the active and/or photoactive layer(s) of any of the various PV devices already discussed (e.g., DSSC, BHJ, hybrid). In some embodiments, each photoactive layer may be capable of absorbing different wavelengths of electromagnetic radiation. Such configuration may be accomplished by any suitable means which will be apparent to one of ordinary skill in the art with the benefit of this disclosure. For example, each photoactive layer may comprise a dye (e.g., where each photoactive layer is composed according to photoactive portions of a DSSC), each dye comprising a different tunable photoactive compound designed with a band gap suitable for absorption of photons of different energies.

An exemplary multi-photoactive-layer PV cell according to some embodiments may be described by reference to the stylized diagram of FIG. 37, which illustrates the basic structure of some such PV cells. FIG. 37 shows first and second photoactive layers (3701 and 3705, respectively) separated by a shared double-sided conductive substrate 3710 (e.g., FIG. 37 shows an architecture of the general nature conductor/insulator/conductor). The two photoactive layers 3701 and 3705, and the shared substrate 3710, are sandwiched between first and second conductive substrates 3715 and 3720. In this exemplary set-up, each photoactive layer 3701 and 3705 comprises a dye in accordance with a DSSC-like configuration. Further, the dye of the first photoactive layer 3701 is capable of absorbing electromagnetic radiation at a first portion of the visible EM spectrum (e.g., incident blue and green light 3750 and 3751), while the dye of the second photoactive layer 3705 is capable of absorbing electromagnetic radiation at a second, different, portion of the visible EM spectrum (e.g., red and yellow light 3755 and 3756). It should be noted that, while not the case in the device illustrated in FIG. 37, devices according to some embodiments may include dyes (or other photoactive layer materials) capable of absorbing radiation in ranges of wavelengths that, while different, nonetheless overlap. Upon excitation in each photoactive layer (e.g., by incident solar radiation), holes may flow from the first photoactive layer 3701 to the first conductive substrate 3715, and likewise from the second photoactive layer 3705 to the second conductive substrate 3720. Concomitant electron transport may accordingly take place from each photoactive layer 3701 and 3705 to the shared conductive substrate 3710. An electrical conductor or conductors (e.g., lead 3735 as in FIG. 37) may provide further transport of holes away from each of the first and second conductive substrates 3715 and 3720 toward a negative direction 3730 of the circuit (e.g., toward a cathode, negative battery terminal, etc.), while a conductor or conductors (e.g., leads 3745 and 3746 as in FIG. 37) may carry electrons away from the shared substrate 3710, toward a positive direction 3735 of the circuit.

In some embodiments, two or more multi-photoactive-layer PV cells may be connected or otherwise electrically coupled (e.g., in series). For example, referring back to the exemplary embodiment of FIG. 37, the wire 3735 conducting electrons away from each of the first and second conductive substrates 3715 and 3720 may in turn be connected to a double-sided shared conductive substrate of a second multi-photoactive-layer PV cell (e.g., a shared conductive substrate corresponding to shared conductive substrate 3710 of the exemplary PV cell of FIG. 37). Any number of PV cells may be so connected in series. The end effect in some embodiments is essentially multiple parallel PV cell pairs electrically coupled in series (wherein each multi-photoactive-layer PV cell with two photoactive layers and a shared double-sided conductive substrate could be considered a pair of parallel PV cells). Similarly, a multi-photoactive-layer PV cell with three photoactive layers and two shared double-sided conductive substrates sandwiched between each photoactive layer could equivalently be considered a trio of parallel PV cells, and so on for multi-photoactive-layer PV cells comprising four, five, and more photoactive layers.

Furthermore, electrically coupled multi-photoactive-layer PV cells may further be electrically coupled to one or more batteries to form a hybrid PV battery according to certain embodiments.

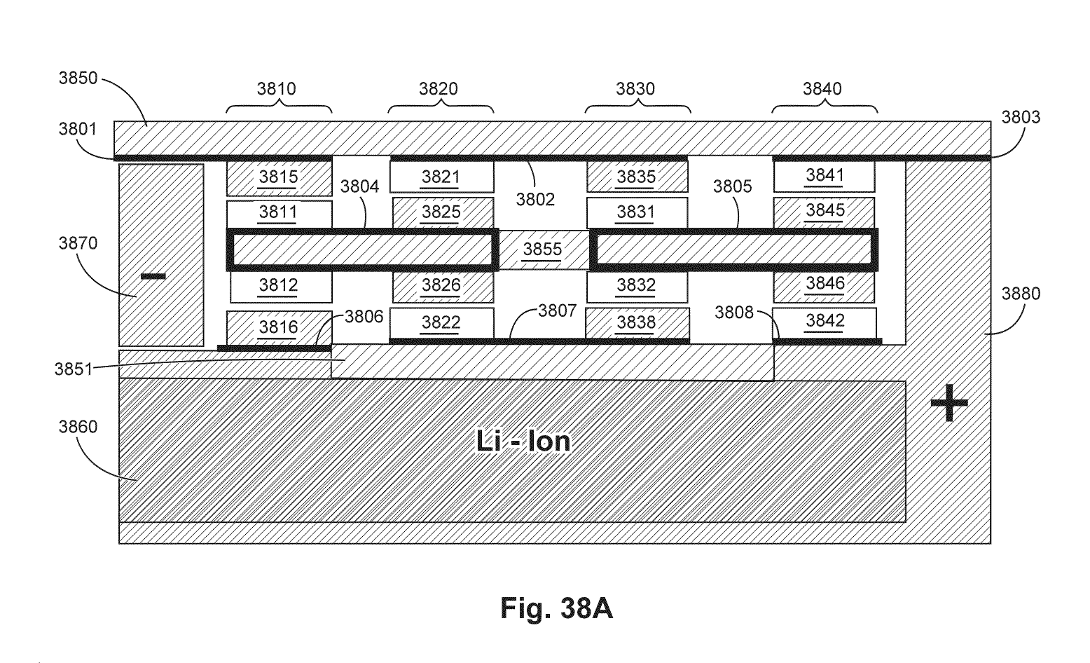

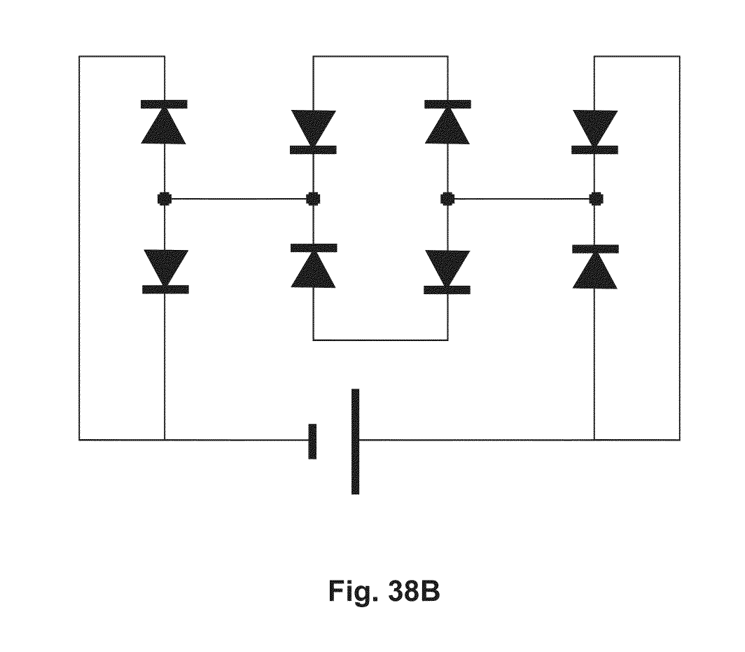

In certain embodiments, the electrical coupling of two or more multi-photoactive-layer PV cells (e.g., series connection of two or more units of parallel PV cell pairs) in series may be carried out in a form similar to that illustrated in FIG. 38A, which depicts a series electrical coupling of four multi-photoactive-layer PV cells 3810, 3820, 3830, and 3840 between a capping anode 3870 and capping cathode 3880. The PV cells 3810, 3820, 3830, and 3840 have a common first outer substrate 3850, and PV cells 3820 and 3830 have a common second outer substrate 3851. In addition, a common shared substrate 3855 runs the length of the series connection, and for each PV cell corresponds to the shared substrate 3710 of the embodiment stylized in FIG. 37. Each of the multi-photoactive-layer PV cells 3810, 3820, 3830, and 3840 shown in the embodiment of FIG. 38A includes two photoactive layers (e.g., photoactive layers 3811 and 3812 in PV cell 3810) and two photoelectrodes (e.g., photoelectrodes 3815 and 3816 in PV cell 3810). A photoactive layer according to this and other corresponding embodiments may include any photoactive and/or active material as disclosed hereinabove (e.g., a tunable photoactive compound, first active material, second active material, and/or one or more interfacial layers), and a photoelectrode may include any substrate and/or conductive material suitable as an electrode as discussed herein. In some embodiments, the arrangement of photoactive layers and photoelectrodes may alternate from cell to cell (e.g., to establish electrical coupling in series). For example, as shown in FIG. 38A, cell 3810 is arranged between the shared outer substrates according to: photoelectrode—photoactive layer—shared substrate—photoactive layer—photoelectrode, while cell 3820 exhibits an arrangement wherein the photoelectrodes and photoactive layers are swapped relative to adjacent cell 3810, and cell 3830 likewise exhibits an arrangement wherein the photoelectrodes and photoactive layers are swapped relative to adjacent cell 3820 (and therefore arranged similarly to cell 3810). FIG. 38A additionally shows a plurality of transparent conductors (3801, 3802, 3803, 3804, 3805, 3806, 3807, and 3808) coupled to portions of each of the common substrates 3850, 3851, and 3855 so as to enable electrical coupling of the PV cells 3810, 3820, 3830, and 3840. In addition, FIG. 38A shows electrical coupling of the series of PV cells to a battery (here, Li-Ion battery 3860) in accordance with some embodiments. Such coupling may enable the PV cells to charge the Li-Ion battery in a similar fashion to the charging of hybrid PV-batteries of some embodiments previously discussed. FIG. 38B is an electrical equivalent diagram showing the resulting current flow in the device of FIG. 38A.

Additives

As previously noted, PV and other devices according to some embodiments may include additives (which may be, e.g., any one or more of acetic acid, propanoic acid, trifluoroacetic acid, chenodeoxycholic acid, deoxycholic acid, 1,8-diiodooctane, and 1,8-dithiooctane). Such additives may be employed as pretreatments directly before dye soaking or mixed in various ratios with a dye to form the soaking solution. These additives may in some instances function, for example, to increase dye solubility, preventing dye molecule clustering, by blocking open active sites, and by inducing molecular ordering amongst dye molecules. They may be employed with any suitable dye, including a photoactive compound according to various embodiments of the present disclosure as discussed herein.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. In particular, every range of values (of the form, “from about a to about b,” or, equivalently, “from approximately a to b,” or, equivalently, “from approximately a-b”) disclosed herein is to be understood as referring to the power set (the set of all subsets) of the respective range of values, and set forth every range encompassed within the broader range of values. Also, the terms in the claims have their plain, ordinary meaning unless otherwise explicitly and clearly defined by the patentee.

What is claimed is:

1. A photovoltaic device comprising:
a first electrode;
an active layer comprising a first active material that comprises a copper-oxide compound, a second active material, and a dye; and
a second electrode;
wherein the active layer is between the first and second electrodes.

2. The photovoltaic device of claim 1 wherein the dye comprises an organic compound comprising:
a primary electron donor moiety comprising at least one substituent selected from the group consisting of: aryl amine, aryl phosphine, aryl arsine, aryl stibine, aryl sulfide, aryl selenide, phenyl, phenol, alkoxy phenyl, dialkoxy phenyl, alkyl phenyl, phenol amine, alkoxy phenyl amine, dialkoxy phenyl amine, alkyl phenyl amine, and combinations thereof;
a core moiety comprising at least one aryl substituent selected from the group consisting of: fluorene, nitrogen heterocycle, benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene, benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof; and
an electron-withdrawing moiety comprising at least one substituent selected from the group consisting of: a carboxylic acid, a monocyanocomplex, a dicyanocomplex, a thiocyanocomplex, an isothiocyanocomplex, and combinations thereof.

3. The photovoltaic device of claim 1 wherein the copper-oxide compound comprises CuₓO_{y} with x in the range of about 1 to about 3 and y in the range of about 0.1 to about 2.

4. The photovoltaic device of claim 1 wherein the copper-oxide compound comprises copper-oxide nanoparticles.

5. The photovoltaic device of claim 1 wherein the second active material forms a mesoporous layer.

6. The photovoltaic device of claim 1 wherein the primary electron donor moiety comprises a multi-aryl amine.

7. The photovoltaic device of claim 6 wherein the primary electron donor moiety comprises an N-(2-naphthyl)anilino substituent.

8. The photovoltaic device of claim 1 wherein the core moiety comprises a nitrogen heterocycle.

9. The photovoltaic device of claim 1 further comprising an additive selected from the group consisting of: acetic acid, propanoic acid, trifluoroacetic acid, chenodeoxycholic acid, deoxycholic acid, 1,8-diiodooctane, 1,8-dithiooctane, and combinations thereof.

10. A photovoltaic device comprising:
a first electrode;
an active layer comprising a first active material, a second active material, a dye, and a thin-coat interfacial layer; and
a second electrode;
wherein the active layer is between the first and second electrodes; and
wherein the first active material comprises a solid-state hole transport material comprising a copper-oxide compound.

11. The photovoltaic device of claim 10 wherein the dye comprises an organic compound comprising:
a primary electron donor moiety comprising at least one substituent selected from the group consisting of: aryl amine, aryl phosphine, aryl arsine, aryl stibine, aryl sulfide, aryl selenide, phenyl, phenol, alkoxy phenyl, dialkoxy phenyl, alkyl phenyl, phenol amine, alkoxy phenyl amine, dialkoxy phenyl amine, alkyl phenyl amine, and combinations thereof;
a core moiety comprising at least one aryl substituent selected from the group consisting of: fluorene, nitrogen heterocycle, benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof; and
an electron-withdrawing moiety comprising at least one substituent selected from the group consisting of: a carboxylic acid, a monocyanocomplex, a dicyanocomplex, a thiocyanocomplex, an isothiocyanocomplex, and combinations thereof.

12. The photovoltaic device of claim 10 wherein the thin-coat interfacial layer comprises a bilayer comprising titania and metal oxide.

13. The photovoltaic device of claim 12 wherein the metal oxide comprises alumina.

14. The photovoltaic device of claim 12 wherein the thin-coat interfacial layer coats at least a portion of either of the first active material and the second active material.

15. The photovoltaic device of claim 14 wherein the thin-coat interfacial layer is coated onto at least a portion of the second active material, wherein the second active material comprises titania and forms a mesoporous layer.

16. The photovoltaic device of claim 10 wherein the thin-coat interfacial layer comprises treated asphaltene.

17. The photovoltaic device of claim 10 further comprising a treated asphaltene interfacial layer deposited onto one of the first electrode and the second electrode.

18. The photovoltaic device of claim 11 wherein the dye is coated onto at least a portion of the thin-coat interfacial layer.

19. A photovoltaic device comprising:
a first electrode;
an active layer comprising a first active material, a second active material, a dye, and a thin-coat interfacial layer comprising a bilayer comprising titania and metal oxide; and
a second electrode;
wherein the active layer is between the first and second electrodes; and
wherein the thin-coat interfacial layer is coated onto at least a portion of either of the first active layer and the second active layer.

20. The photovoltaic device of claim 19 wherein the dye comprises an organic compound comprising:
a primary electron donor moiety comprising at least one substituent selected from the group consisting of: aryl amine, aryl phosphine, aryl arsine, aryl stibine, aryl sulfide, aryl selenide, phenyl, phenol, alkoxy phenyl, dialkoxy phenyl, alkyl phenyl, phenol amine, alkoxy phenyl amine, dialkoxy phenyl amine, alkyl phenyl amine, and combinations thereof;
a core moiety comprising at least one aryl substituent selected from the group consisting of: fluorene, nitrogen heterocycle, benzothiophene, dibenzothiophene, naphthothiophene, dinaphthothiophene, benzonaphthothiophene, biphenyl, naphthyl, benzene, benzothiazole, benzothiadiazole, benzo[b]naphtha[2,3-d]thiophene, 4H-cyclopenta[1,2-b:5,4-b′]bisthiophene, dinaphtho[2,3-d]thiophene, thieno[3,2-b]thiophene, naphthalene, anthracene, benzo[b][1]benzosilole, quinoxalino[2,3-b]quinoxaline, pyrazino[2,3-b]quinoxaline, pyrazino[2,3-b]pyrazine, imidazo[4,5-b]quinoxaline, imidazo[4,5-b]pyrazine, thiazolo[4,5-b]quinoxaline, thiazolo[4,5-b]pyrazine, 1,3-benzothiazole, and combinations thereof; and
an electron-withdrawing moiety comprising at least one substituent selected from the group consisting of: a carboxylic acid, a monocyanocomplex, a dicyanocomplex, a thiocyanocomplex, an isothiocyanocomplex, and combinations thereof.

21. The photovoltaic device of claim 19 wherein the metal oxide comprises alumina.

22. The photovoltaic device of claim 19 wherein the first active material comprises a liquid electrolyte.

23. The photovoltaic device of claim 19 wherein the first active material comprises a solid-state hole transport material.

24. The photovoltaic device of claim 21 wherein the solid-state hole transport material comprises a copper-oxide compound.

25. The photovoltaic device of claim 21 wherein the copper-oxide compound comprises CuₓO_{y} with x in the range of about 1 to about 3 and y in the range of about 0.1 to about 2.

26. The photovoltaic device of claim 21 wherein the copper-oxide compound comprises copper-oxide nanoparticles.

27. The photovoltaic device of claim 19 wherein the second active material forms a mesoporous layer.

28. The photovoltaic device of claim 19 further comprising a treated asphaltene interfacial layer deposited onto one of the first electrode and the second electrode.

29. The photovoltaic device of claim 19 further comprising an additive selected from the group consisting of: acetic acid, propanoic acid, trifluoroacetic acid, chenodeoxycholic acid, deoxycholic acid, 1,8-diiodooctane, 1,8-dithiooctane, and combinations thereof.
